(19) United States
(12) Patent Application Publication
(10) Pub. No.: US 2015/0275029 A1
(43) Pub. Date: Oct. 1, 2015

(54) SEALING RESIN COMPOSITION, SEALING FILM, WIRING BOARD, TFT DEVICE, OLED DEVICE, AND LED DEVICE

(71) Applicant: FUJIFILM CORPORATION, Tokyo (JP)

(72) Inventors: Yasuaki MATSUSHITA, Kanagawa (JP); Toyohisa OYA, Kanagawa (JP); Tokihiko MATSUMURA, Kanagawa (JP)

(73) Assignee: FUJIFILM CORPORATION, Tokyo (JP)

(21) Appl. No.: 14/728,139

(22) Filed: Jun. 2, 2015

Related U.S. Application Data
(63) Continuation of application No. PCT/JP2013/082950, filed on Dec. 9, 2013.

(30) Foreign Application Priority Data
Dec. 13, 2012 (JP) 2012-272280
Mar. 29, 2013 (JP) 2013-073081

(51) Int. Cl. C09D 137/00; H01L 23/10

(52) U.S. Cl. CPC C09D 137/00; H01L 23/10; C08K 5/101

(57) ABSTRACT

A sealing resin composition, which coats silver wiring or a laminate including the silver wiring, comprises: a fluorine-based resin (A); and a migration inhibitor (B) having a fluorine content rate of equal to or more than 35 mass % and less than 65 mass %, wherein the mass ratio ((B)/(A)) of the migration inhibitor (B) to the fluorine-based resin (A) is equal to or more than 0.0010 and less than 0.10.

### CROSS-REFERENCE TO RELATED APPLICATIONS

This application is a Continuation of PCT International Application No. PCT/JP2013/082950 filed on Dec. 9, 2013, which claims priority under 35 U.S.C. §119(a) to Japanese Application No. 2012-272280 filed on Dec. 13, 2012 and Japanese Application No. 2013-073081 filed on Mar. 29, 2013. Each of the above application(s) is hereby expressly incorporated by reference, in its entirety, into the present application.

### BACKGROUND OF THE INVENTION

The present invention relates to a sealing resin composition and a sealing film. Particularly, the present invention relates to a sealing resin composition and a sealing film, each of which contains a fluorine-based resin and a migration inhibitor having a predetermined fluorine content rate in predetermined amounts.

The present invention also relates to a wiring board, a TFT device, an OLED device, and an LED device, each of which includes the sealing film.

In recent years, with the miniaturization, high integration and high performance of electronic components, the microfabrication of metal wiring has progressed. Consequently, the electromigration (hereinafter, also referred to as “ion migration”) occurring between the metal wiring causes a serious problem in that wiring reliability is decreased. Particularly, in the case of metal wiring formed using silver, the problem is remarkably serious.

In order to solve this problem, JP 59-151491 A suggests a method of suppressing ion migration by forming an insulating material layer containing a fluorine-based resin on metal wiring.

### SUMMARY OF THE INVENTION

Meanwhile, in recent years, as the microfabrication of metal wiring has progressed, the characteristics required for insulation reliability between metal wiring have been more and more raised.

The present inventors examined the insulation reliability between metal wiring using the method described in JP 59-151491 A. As a result, it was found that the insulation reliability between metal wiring obtained by the method does not satisfy the level currently required and further improvement thereof is required.

As the method of suppressing ion migration, there is a method of also using a so-called migration inhibitor. However, generally, the compatibility of a migration inhibitor with respect to a fluorine-based resin is low, and thus, there is a problem in that the planar characteristics of the formed sealing layer are deteriorated. Therefore, it is difficult to use a migration inhibitor.

In view of the above circumstances, an object of the present invention is to provide a sealing resin composition which can be applied to silver wiring and a laminate including the silver wiring, and can form a sealing film exhibiting excellent ion migration-inhibiting ability and excellent planar characteristics.

Another object of the present invention is to provide a sealing film and a wiring board including the sealing film.

As a result of conducting intensive examination, the present inventors found that the above problems can be solved by using a fluorine-based resin and a migration inhibitor having a predetermined fluorine content rate, and based on this finding, the present invention was accomplished.

That is, the above objects can be accomplished by the following means.

(1) A sealing resin composition, which coats silver wiring or a laminate including the silver wiring, comprising:

a fluorine-based resin (A); and

a migration inhibitor (B) having a fluorine content rate of equal to or more than 35 mass % and less than 65 mass %,

wherein the mass ratio ((B)/(A)) of the migration inhibitor (B) to the fluorine-based resin (A) is equal to or more than 0.0010 and less than 0.10.

(2) The sealing resin composition according to (1), wherein the migration inhibitor (B) is at least one selected from the group consisting of compounds represented by General Formulae (1) to (5) described later, a compound represented by General Formula (22) described later, a compound represented by General Formula (23) described later, and a compound having a group represented by General Formula (24) described later and a group represented by General Formula (25) described later.

(3) The sealing resin composition according to (2), wherein the compound represented by the General Formula (1) described later is at least one selected from the group consisting of compounds represented by General Formulae (6) to (21) described later.

(4) The sealing resin composition according to (2) or (3),

wherein the compound represented by General Formula (5) described later is at least one selected from the group consisting of compounds represented by General Formulae (51) to (54) described later.

(5) The sealing resin composition according to (4),

wherein the migration inhibitor (B) is at least one selected from the group consisting of the compounds represented by General Formula (6) described later, General Formula (7) described later, General Formula (10) described later, General Formula (11) described later, General Formula (21) described later, General Formula (51) described later, General Formula (53) described later, and General Formula (54) described later.

(6) The sealing resin composition according to any one of (1) to (5),

wherein the fluorine-based resin (A) has at least a repeating unit represented by General Formula (P-1) described later.

(7) The sealing resin composition according to any one of (1) to (6),

wherein the fluorine-based resin (A) has a silicon-containing group that has a hydroxyl group or a hydrolyzable group bonded to a silicon atom and that can be crosslinked by forming a siloxane bond.

(8) A sealing film, which coats silver wiring or a laminate including the silver wiring, comprising:

a fluorine-based resin (A); and

a migration inhibitor (B) having a fluorine content rate of equal to or more than 35 mass % and less than 65 mass %,

wherein the mass ratio ((B)/(A)) of the migration inhibitor (B) to the fluorine-based resin (A) is equal to or more than 0.0010 and less than 0.10.

(9) The sealing film according to (8), wherein the migration inhibitor (B) is at least one selected from the group consisting of compounds represented by General Formulae (1) to (5) described later, a compound represented by General Formula (22) described later, a compound represented by General Formula (23) described later, and a compound having a group represented by General Formula (24) described later and a group represented by General Formula (25) described later.

(10) The sealing film according to (9), wherein the compound represented by the General Formula (1) described later is at least one selected from the group consisting of compounds represented by General Formulae (6) to (21) described later.

(11) The sealing film according to (9) or (10),

wherein the compound represented by General Formula (5) described later is at least one selected from the group consisting of compounds represented by General Formulae (51) to (54) described later.

(12) The sealing film according to (11),

wherein the migration inhibitor (B) is at least one selected from the group consisting of the compounds represented by General Formula (6) described later, General Formula (7) described later, General Formula (10) described later, General Formula (11) described later, General Formula (21) described later, General Formula (51) described later, General Formula (53) described later, and General Formula (54) described later.

(13) The sealing film according to any one of (8) to (12),

wherein the fluorine-based resin (A) is a polymer compound having at least a repeating unit represented by General Formula (P-1) described later.

(14) The sealing film according to any one of (8) to (13),

wherein the fluorine-based resin (A) has a silicon-containing group that has a hydroxyl group or a hydrolyzable group bonded to a silicon atom and that can be crosslinked by forming a siloxane bond.

(15) A wiring board comprising:

a substrate;

silver wiring disposed on the substrate; and

the sealing film according to any one of (8) to (14) disposed on the silver wiring.

(16) A TFT device comprising the sealing film any one of (8) to (14).

(17) An OLED device comprising the sealing film according to any one of (8) to (14).

(18) An LED device comprising the sealing film according to any one of (8) to (14).

According to the present invention, it is possible to provide a sealing resin composition which can be applied to silver wiring and a laminate including the silver wiring, and can form a sealing film exhibiting excellent ion migration-inhibiting ability and excellent planar characteristics.

In addition, according to the present invention, it is possible to provide a sealing film and a wiring board including the sealing film.

### BRIEF DESCRIPTION OF THE DRAWINGS

FIG. 1 is a schematic cross-sectional view showing a preferred embodiment of a wiring board of the present invention.

### DETAILED DESCRIPTION OF THE INVENTION

Hereinafter, preferred embodiments of a sealing resin composition, a sealing film, and a wiring board of the present invention will be described.

First, the characteristics of the present invention will be specifically described in comparison with the conventional technique.

In the present invention, it was found that if a fluorine-based resin and a migration inhibitor having a predetermined fluorine content rate are used in predetermined amounts, desired effects can be obtained. If a predetermined amount of fluorine atoms is contained in the migration inhibitor, the compatibility (affinity) of the migration inhibitor with the fluorine-based resin is improved, bleed-out of the migration inhibitor from the fluorine-based resin is suppressed, and thus, planar characteristics are improved. In addition, since it becomes easier for the migration inhibitor to remain in the fluorine-based resin, ion migration-inhibiting ability is further improved.

Hereinafter, first, the sealing resin composition will be described in detail, and then, the sealing film and the wiring beard will be described in detail.

<Sealing Resin Composition>

The sealing resin composition contains a fluorine-based resin (A) and a migration inhibitor (B) in predetermined amounts.

First, the fluorine-based resin (A) and the migration inhibitor (B) will be described in detail, and then embodiments of the sealing resin composition will be described in detail.

(Fluorine-Based Resin (A))

The fluorine-based resin refers to a resin containing a fluorine atom. The type of the fluorine-based resin is not particularly limited as long as it contains a fluorine atom. Here, the contact angle of the fluorine-based resin with water is preferably equal to or more than 85°, and more preferably equal to or more than 95°.

Examples of the fluorine-based resin include polyvinylidene fluoride (PVDF), polytetrafluoroethylene (PTFE), a tetrafluoroethylene-ethylene copolymer (ETFE), a tetrafluoroethylene-perfluoroalkoxyethylene copolymer (PFA), and a perfluoro(butenyl vinyl ether) cyclized polymer.

Further, the fluorine-based resin may be a resin obtained by polymerizing fluorine-containing (meth)acrylic monomers. Examples of the fluorine-containing (meth)acrylic monomer include 1H,1H,2H,2H-heptadecafluorodecyl methacrylate, 1H,1H,5H-octafluoropentyl methacrylate, 2,2,3,3-tetrafluoropropyl methacrylate, 2,2,2-trifluoroethyl methacrylate, 1H,1H,2H,2H-heptadecafluorodecyl acrylate, 1H,1H,5H-octafluoropentyl acrylate, 2,2,3,3-tetrafluoropropyl acrylate, 2,2,2-trifluoroethyl acrylate, perfluorooctylethyl methacrylate, and perfluorooctylethyl acrylate.

As the fluorine-based resin, commercially available products, such as CYTOP (registered trademark) manufactured by Asahi Glass Co., Ltd., TEFLON (registered trademark) AF manufactured by DuPont Corporation, polyvinylidene fluoride, LUMIFLON manufactured by Asahi Glass Co., Ltd., and OPSTAR manufactured by JSR Corporation, can also be used.

The weight average molecular weight of the fluorine-based resin is not particularly limited. However, from the viewpoint of ion migration-inhibiting ability and film-forming ability, it is preferably 5000 to 1000000, and more preferably 20000 to 500000.

As one preferred embodiment of the fluorine-based resin, the fluorine content rate of the fluorine-based resin is preferably equal to or more than 65 mass %, and more preferably equal to or more than 67.5 mass %. When the fluorine content rate is within the above range, the ion migration-inhibiting ability of the sealing layer to be formed is better. The upper limit thereof is not particularly limited. However, from the viewpoint of the synthesis thereof, it is generally equal to or less than 77.5 mass % in many cases.

The fluorine content rate refers to a percentage (content rate) of mass occupied by fluorine atoms in the total molecular weight of the fluorine-based resin.

As another preferred embodiment of the fluorine-based resin, the fluorine-based resin preferably has at least a repeating unit represented by General Formula (P-1) below. When the fluorine-based resin contains the repeating unit, the fluorine-based resin is excellent in solubility in a solvent and in coating properties, and is also excellent in the compatibility with the migration inhibitor.

The content rate of the repeating unit represented by General Formula (P-1) in the fluorine-based resin is not particularly limited. However, from the viewpoint of better effects of the present invention, it is preferably equal to or more than 60 mol % and equal to or less than 98 mol % with respect to the total repeating units.

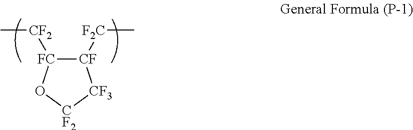

As another preferred embodiment of the fluorine-based resin, the fluorine-based resin preferably has a silicon-containing group that has a hydroxyl group or a hydrolyzable group bonded to a silicon atom and that can be crosslinked by forming a siloxane bond. (hereinafter, briefly referred to as “a silicon-containing group”). If the fluorine-based resin contains the silicon-containing group, adhesiveness of the sealing layer (sealing film) formed from the sealing resin composition with respect to various substrates and layers adjacent thereto is further improved. The bonding position of the silicon-containing group in the fluorine-based resin is not particularly limited, and may be either a terminal or a side chain.

More specifically, the silicon-containing group is preferably a group represented by General Formula (P-2) below.

—Si(Rₐ)ₓ(R_{b})_{y} General Formula (P-2)

Rₐ represents a hydroxyl group or a hydrolyzable group. R_{b} represents a non-hydrolyzable group. x represents an integer of 1 to 3, y represents an integer of 0 to 2, and a relationship of x+y=3 is satisfied.

The hydrolyzable group represents a group capable of forming a silanol group or a group capable of forming a siloxane condensate. Specific examples thereof include a halogen group, an alkoxy group, an acyloxy group, an isocyanate group, and the like. Among these, an alkoxy group (carbon number of 1 to 2 is preferable) is preferable.

Examples of the non-hydrolyzable group include a hydrogen atom; an aliphatic hydrocarbon group such as an alkyl group, an alkenyl group, and an alkynyl group; an aromatic hydrocarbon group such as an aryl group; and a group composed of any combination of these.

(Migration Inhibitor (B))

The migration inhibitor (anti-migration agent) is a compound that suppresses ion migration by trapping silver ions or the like.

The fluorine content rate of the migration inhibitor used in the present invention is equal to or more than 35 mass % and less than 65 mass %. Especially, from the viewpoints that the ion migration-inhibiting ability of the sealing layer (sealing film) formed from the sealing resin composition is more excellent and the planar characteristics thereof are also more excellent, the fluorine content rate thereof is preferably 40 mass % to 60 mass %, and more preferably 42 mass % to 55 mass %.

When the fluorine content rate is less than 35 mass %, the compatibility of the migration inhibitor with the fluorine-based resin is deteriorated, and thus, the ion migration-inhibiting ability and planar characteristics of the sealing layer are deteriorated. When the fluorine content rate is equal to or more than 65 mass %, the rate of migration-inhibiting sites in a molecule is reduced, and thus, it is necessary to practically add a large amount of migration inhibitors, which leads to occurrence of problems in the solubility, the compatibility, and the like of the migration inhibitor.

Here, the fluorine content rate refers to a percentage (content rate) (%) of mass occupied by fluorine atoms in the total molecular weight of the migration inhibitor. That is, the fluorine content rate is a value represented by {(number of fluorine atoms in the compound)×(atomic weight of fluorine)/(the total molecular weight of the compound)}×100(%). For example, when the total molecular weight of the migration inhibitor is 100 and three fluorine atoms are contained therein, the percentage (%) of mass occupied by the fluorine atoms is calculated as {(19×3)/100}×100, that is, 57 mass %.

The type of the migration inhibitor is not particularly limited as long as the migration inhibitor has the above fluorine content rate and ion migration-inhibiting ability. Examples of the migration inhibitor include phenol-based compounds, compounds having a mercapto group or a free radical group, antioxidants, and the like.

Among these, from the viewpoint that the ion migration-inhibiting ability of the sealing layer (sealing film) formed from the sealing resin composition is further improved, compounds represented by General Formulae (1) to (5), a compound represented by General Formula (22), a compound represented by General Formula (23), and a compound having a group represented by General Formula (24) and a group represented by General Formula (25), which will be described later, are preferable.

(Compound Represented by General Formula (1))

First, the compound represented by General Formula (1) will be described.

P—(CR₁═Y)ₙ-Q General Formula (1)

In the General Formula (1), each of P and Q is independently OH, NR₂R₃, or CHR₄R₅. However, when n is 0, neither both P and Q are CHR₄R₅, nor both P and Q are OH. Y represents CR₆ or a nitrogen atom.

In the General Formula (1), each of R₂ and R₃ is independently a hydrogen atom or a group which can be substituted with a nitrogen atom.

The group which can be substituted with a nitrogen atom is not particularly limited as long as it can be substituted with a nitrogen atom, and examples thereof include an alkyl group (including a cycloalkyl group), an alkenyl group (including a cycloalkenyl group and a bicycloalkenyl group), an alkynyl group, an aryl group, a heterocyclic group, alkyl and aryl sulfinyl groups, alkyl and aryl sulfonyl groups, an acyl group, an alkoxy carbonyl group, an aryloxy carbonyl group, a carbamoyl group, a phosphino group, a phosphinyl group, and a group composed of any combination of these.

More specifically, preferred examples thereof include the following groups <A> to <M>.

<A> An alkyl group which is a linear, branched, or cyclic substituted or unsubstituted alky group. Examples of the alkyl group include an alkyl group (preferably, an alkyl group having 1 to 30 carbon atoms, for example, methyl, ethyl, n-propyl, isopropyl, t-butyl, n-octyl, eicosyl, 2-chloroethyl, 2-cyanoethyl, or 2-ethylhexyl), a cycloalkyl group (preferably, a substituted or unsubstituted cycloalkyl group having 3 to 30 carbon atoms, for example, cyclohexyl, cyclopentyl, or 4-n-dodecylcyclohexyl), and a bicycloalkyl group (preferably, a substituted or unsubstituted bicycloalkyl group having 5 to 30 carbon atoms, that is, a monovalent group obtained by removing one hydrogen atom from a bicycloalkane having 5 to 30 carbon atoms, for example, bicyclo[1.2.2]heptane-2-yl, or bicyclo[2.2.2]octane-3-yl). Examples of the alkyl group further include a tricyclo structure having many cyclic structures and the like. Among the substituents to be described below, an alkyl group (for example, an alkyl group of an alkylthio group) represents the aforementioned alkyl group.

<B> An alkenyl group which is a linear, branched, or cyclic substituted or unsubstituted alkenyl group. Examples of the alkenyl group include an alkenyl group (preferably, a substituted or unsubstituted alkenyl group having 2 to 50 carbon atoms, for example, vinyl, allyl, prenyl, geranyl, or oleyl), a cycloalkenyl group (preferably, a substituted or unsubstituted cycloalkenyl group having 3 to 30 carbon atoms, that is, a monovalent group obtained by removing one hydrogen atom from cycloalkene having 3 to 30 carbon atoms, for example, 2-cyclopentene-1-yl or 2-cyclohexene-1-yl), and a bicycloalkenyl group (a substituted or unsubstituted bicycloalkenyl group, preferably a substituted or unsubstituted bicycloalkenyl group having 5 to 30 carbon atoms, that is, a monovalent group obtained by removing one hydrogen atom from bicycloalkene having one double bond, for example, bicyclo[2.2.1]hept-2-en-1-yl or bicyclo[2.2.2]oct-2-en-4-yl.

<C> An alkynyl group (preferably, a substituted or unsubstituted alkynyl group having 2 to 30 carbon atoms, for example, ethynyl, propargyl, or a trimethylsilyl ethynyl group).

<D> An aryl group (preferably, a substituted or unsubstituted aryl group having 6 to 50 carbon atoms, for example, phenyl, p-tolyl, naphthyl, m-chlorophenyl, or o-hexadecanoylaminophenyl).

<E> A heterocyclic group (preferably, a monovalent group obtained by removing one hydrogen atom from a 5- or 6-membered substituted or unsubstituted aromatic or non-aromatic heterocyclic compound, and more preferably a 5- or 6-membered aromatic heterocyclic group having 3 to 30 carbon atoms, for example, 2-furanyl, 2-thienyl, 2-pyrimidinyl, or 2-benzothiazolinyl).

<F> Alkyl and aryl sulfinyl groups (preferably, a substituted or unsubstituted alkylsulfinyl group having 1 to 30 carbon atoms and a substituted or unsubstituted arylsulfinyl group having 6 to 30 carbon atoms, for example, methylsulfinyl, ethylsulfinyl, phenylsulfinyl, or p-methylphenylsulfinyl).

<G> Alkyl and aryl sulfonyl groups (preferably, a substituted or unsubstituted alkylsulfonyl group having 1 to 30 carbon atoms and a substituted or unsubstituted arylsulfonyl group having 6 to 30 carbon atoms, for example, methylsulfonyl, ethylsulfonyl, phenylsulfonyl, or p-methylphenylsulfonyl).

<H> An acyl group (preferably, a formyl group, a substituted or unsubstituted alkylcarbonyl group having 2 to 30 carbon atoms, a substituted or unsubstituted arylcarbonyl group having 7 to 30 carbon atoms, and a substituted or unsubstituted heterocyclic carbonyl group having 4 to 30 carbon atoms in which a carbon atom is bonded with a carbonyl group, for example, acetyl, pivaloyl, 2-chloroacetyl, stearoyl, benzoyl, p-n-octyloxyphenylcarbonyl, 2-pyridylcarbonyl, or 2-furylcarbonyl).

<I> An aryloxy carbonyl group (preferably, a substituted or unsubstituted aryloxy carbonyl group having 7 to 30 carbon atoms, for example, phenoxycarbonyl, o-chlorophenoxycarbonyl, m-nitrophenoxycarbonyl, or p-t-butyl-phenoxycarbonyl).

<J> An alkoxycarbonyl group (preferably, a substituted or unsubstituted alkoxycarbonyl group having 2 to 30 carbon atoms, for example, methoxycarbonyl, ethoxycarbonyl, t-butoxycarbonyl, or n-octadecyloxycarbonyl).

<K> A carbamoyl group (preferably, a substituted or unsubstituted carbamoyl group having 1 to 30 carbon atoms, for example, carbamoyl, N-methylcarbamoyl, N,N-dimethylcarbamoyl, N,N-di-n-octylcarbamoyl, or N-(methylsulfonyl)carbamoyl).

<L> A phosphino group (preferably, a substituted or unsubstituted phosphino group having 2 to 30 carbon atoms, for example, dimethylphosphino, diphenylphosphino, or methylphenoxyphosphino).

<M> A phosphinyl group (preferably, a substituted or unsubstituted phosphinyl group having 2 to 30 carbon atoms, for example, phosphinyl, dioctyloxyphosphinyl, or diethoxyphosphinyl).

Among the above functional groups, functional groups having a hydrogen atom may be further substituted by removing the hydrogen atom.

The alkyl group represented by R₂ and R₃ in the General Formula (1) is a linear, branched, or cyclic substituted or unsubstituted alkyl group. The alkyl group has preferably 1 to 50 carbon atoms, more preferably 1 to 30 carbon atoms, and particularly preferably 1 to 20 carbon atoms.

Preferable examples of the alkyl group include methyl, ethyl, n-propyl, isopropyl, cyclopropyl, butyl, isobutyl, t-butyl, sec-butyl, pentyl, isopentyl, neopentyl, t-pentyl, hexyl, cyclohexyl, heptyl, cyclopentyl, octyl, 2-ethylhexyl, nonyl, decyl, dodecyl, tetradecyl, hexadecyl, octadecyl, eicosyl, docosyl, triacontyl, and the like. More preferable examples thereof include methyl, ethyl, n-propyl, isopropyl, butyl, isobutyl, t-butyl, sec-butyl, t-butyl, pentyl, isopentyl, neopentyl, hexyl, cyclohexyl, octyl, 2-ethylhexyl, dodecyl, hexadecyl, and octadecyl. Particularly preferable examples thereof include methyl, ethyl, n-propyl, isopropyl, butyl, t-butyl, pentyl, isopentyl, hexyl, cyclohexyl, octyl, 2-ethylhexyl, dodecyl, hexadecyl, and octadecyl.

The alkyl group may include a linking group such as —CO—, —NH—, —O—, —S—, or a group composed of any combination of these. Here, when the linking group is included in the alkyl group, the position of the linking group is not particularly limited, and may be the terminal of the alkyl group. —S—Rₓ (Rₓ: alkyl group) may be exemplified.

The alkyl group represented by R₂ and R₃ may further include a substituent.

Examples of the substituent include a halogen atom, an alkyl group (including a cycloalkyl group), an alkenyl group (including a cycloalkenyl group and a bicycloalkenyl group), an alkynyl group, an aryl group, a heterocyclic group, a cyano group, a hydroxyl group, a nitro group, a carboxyl group, an alkoxy group, an aryloxy group, a silyloxy group, a heterocycloxy group, an acyloxy group, a carbamoyloxy group, an alkoxycarbonyloxy group, an aryloxycarbonyloxy group, an amino group (including an anilino group), an acylamino group, an amino carbonyl amino group, an alkoxycarbonyl amino group, an aryloxycarbonylamino group, a sulfamoylamino croup, alkyl and aryl sulfonyl amino group, a mercapto group, an alkylthio group, an arylthio group, a heterocyclic thio group, a sulfamoyl group, a sulfo group, alkyl and aryl sulfinyl groups, alkyl and aryl sulfonyl groups, an acyl group, an aryloxy carbonyl group, an alkoxycarbonyl group, a carbamoyl group, aryl and heterocyclic azo groups, an imide group, a phosphino group, a phosphinyl group, a phosphinyloxy group, a phosphinylamino group, a silyl group, and a group composed of any combination of these.

More specifically, examples of the substituent include a halogen atom (for example, a chlorine atom, a bromine atom, or an iodine atom); an alkyl group; and an alkenyl group. Here, the alkyl group represents a linear, branched, or cyclic substituted or unsubstituted alkyl group. Examples of the alkyl group include an alkyl group (preferably, an alkyl group having 1 to 30 carbon atoms, for example, methyl, ethyl, n-propyl, isopropyl, t-butyl, n-octyl, eicosyl, 2-chloroethyl, 2-cyanoethyl, or 2-ethylhexyl), a cycloalkyl group (preferably, a substituted or unsubstituted cycloalkyl group having 3 to 30 carbon atoms, for example, cyclohexyl, cyclopentyl, or 4-n-dodecyl cyclohexyl), and a bicycloalkyl group (preferably, a substituted or unsubstituted bicycloalkyl group having 5 to 30 carbon atoms, that is, a monovalent group obtained by removing one hydrogen atom from bicycloalkane having 5 to 30 carbon atoms, for example, bicyclo[1.2.2]heptane-2-yl or bicyclo[2.2.2]octane-3-yl. Examples of the alkyl group further include a tricyclo structure having many cyclic structures, and the like. Among the substituents to be described below, an alkyl group (for example, an alkyl group of an alkylthio group) represents the aforementioned alkyl group.

The alkenyl group represents a linear, branched, or cyclic substituted or unsubstituted alkenyl group. Examples of the alkenyl group include an alkenyl group (preferably, a substituted or unsubstituted alkenyl group having 2 to 30 carbon atoms, for example, vinyl, allyl, prenyl, geranyl, or oleyl), a cycloalkenyl group (preferably, a substituted or unsubstituted cycloalkenyl group having 3 to 30 carbon atoms, that is, a monovalent group obtained by removing one hydrogen atom from cycloalkene having 3 to 30 carbon atoms, for example, 2-cyclopentene-1-yl or 2-cyclohexen-1-yl), and a bicycloalkenyl group (a substituted or unsubstituted bicycloalkenyl group, preferably, a substituted or unsubstituted bicycloalkenyl group having 5 to 30 carbon atoms, that is, a monovalent group obtained by removing one hydrogen atom from bicycloalkene having one double bond, for example, bicyclo[2.2.1]hept-2-en-1-yl or bicyclo[2.2.2]oct-2-en-4-yl).

Examples of the substituent further include an alkynyl group (preferably, a substituted or unsubstituted alkynyl group having 2 to 50 carbon atoms, for example, ethynyl, propargyl, or a trimethylsilylethynyl group);

an aryl group (preferably, a substituted or unsubstituted aryl group having 6 to 30 carbon atoms, for example, phenyl, p-tolyl, naphthyl, m-chlorophenyl, or o-hexadecanoylaminophenyl); a heterocyclic group (preferably, a monovalent group obtained by removing one hydrogen atom from a 5- or 6-membered substituted or unsubstituted aromatic or non-aromatic heterocyclic compound, and more preferably a 5- or 6-membered aromatic heterocyclic group having 3 to 30 carbon atoms, for example, 2-furanyl, 2-thienyl, 2-pyrimidinyl, or 2-benzothiazolinyl);
a cyano group; a hydroxyl group; a nitro group; a carboxyl group; an alkoxy group (preferably, a substituted or unsubstituted alkoxy group having 1 to 30 carbon atoms, for example, methoxy, ethoxy, isopropoxy, t-butoxy, n-octyloxy, or 2-methoxyethoxy); an aryloxy group (preferably, a substituted or unsubstituted aryloxy group having 6 to 30 carbon atoms, for example, phenoxy, 2-methylphenoxy, 4-t-butylphenoxy, 3-nitrophenoxy, or 2-tetradecanoyl aminophenoxy); a silyloxy group (preferably, a silyloxy group having 3 to 20 carbon atoms, for example, trimethylsilyloxy or t-butyldimethylsilyloxy); a heterocycloxy group (preferably, a substituted or unsubstituted heterocycloxy group having 2 to 30 carbon atoms, for example, 1-phenyl tetrazole-5-oxy or 2-tetrahydropyranyloxy); an acyloxy group (preferably, a formyloxy group, a substituted or unsubstituted alkylcarbonyloxy group having 2 to 30 carbon atoms, and a substituted or unsubstituted arylcarbonyloxy group having 6 to 30 carbon atoms, for example, formyloxy, acetyloxy, pivaloyloxy, stearoyloxy, benzoyloxy, or p-methoxyphenylcarbonyloxy); a carbamoyloxy group (preferably a substituted or unsubstituted carbamoyloxy group having 1 to 30 carbon atoms, for example, N,N-dimethylcarbamoyloxy, N,N-diethylcarbamoyloxy, morpholino carbonyloxy, N,N-di-n-octyl aminocarbonyloxy, or N-n-octylcarbamoyloxy); an alkoxycarbonyloxy group (preferably a substituted or unsubstituted alkoxycarbonyloxy group having 2 to 30 carbon atoms, for example, methoxycarbonyloxy, ethoxycarbonyloxy, t-butoxycarbonyloxy, or n-octyl carbonyloxy); an aryloxycarbonyloxy group (preferably a substituted or unsubstituted aryloxycarbonyloxy group having 7 to 30 carbon atoms, for example, phenoxycarbonyloxy, p-methoxyphenoxy carbonyloxy, or p-n-hexadecyloxy phenoxycarbonyloxy); an amino group (preferably, an amino group, a substituted or unsubstituted alkylamino group having 1 to 30 carbon atoms, and a substituted or unsubstituted anilino group having 6 to 30 carbon atoms, for example, amino, methylamino, dimethylamino, anilino, N-methyl-anilino, or diphenylamino); an acylamino group (preferably, a formylamino group, a substituted or unsubstituted alkyl carbonylamino group having 1 to 30 carbon atoms, and a substituted or unsubstituted arylcarbonylamino group having 6 to 30 carbon atoms, for example, formylamino, acetylamino, pivaloylamino, lauroylamino, benzoylamino, or 3,4,5-tri-n-octyloxyphenylcarbonylamino); an aminocarbonylamino group (preferably, a substituted or unsubstituted aminocarbonylamino group having 1 to 30 carbon atoms, for example, carbamoylamino, N,N-dimethylaminocarbonyl amino, N,N-diethylamino carbonylamino, or morpholinocarbonylamino); an alkoxycarbonylamino group (preferably, a substituted or unsubstituted alkoxycarbonylamino group having 2 to 30 carbon atoms, for example, methoxycarbonylamino, ethoxycarbonylamino, t-butoxycarbonylamino, n-octadecyloxycarbonylamino, or N-methyl-methoxy carbonyl amino); an aryloxycarbonylamino group (preferably, a substituted or unsubstituted aryloxycarbonylamino group having 7 to 30 carbon atoms, for example, phenoxycarbonylamino, p-chloro phenoxycarbonylamino, or m-n-octyloxy phenoxycarbonylamino); a sulfamoylamino group (preferably, a substituted or unsubstituted sulfamoylamino group having 0 to 30 carbon atoms, for example, sulfamoylamino, N,N-dimethylaminosulfonylamino, or N-n-octyl aminosulfonylamino); alkyl and aryl sulfonylamino groups (preferably a substituted or unsubstituted alkylsulfonylamino having 1 to 30 carbon atoms, and a substituted or unsubstituted arylsulfonylamino having 6 to 30 carbon atoms, for example, methylsulfonylamino, butylsulfonylamino, phenyl sulfonylamino, 2,3,5-trichlorophenyl sulfonylamino, or p-methylphenyl sulfonylamino);
a mercapto group; an alkylthio group (preferably, a substituted or unsubstituted alkylthio group having 1 to 30 carbon atoms, for example, methylthio, ethylthio, or n-hexadecylthio); an arylthio group (preferably, a substituted or unsubstituted arylthio group having 6 to 30 carbon atoms, for example, phenylthio, p-chlorophenylthio, or m-methoxyphenylthio); a heterocyclic thio group (preferably a substituted or unsubstituted heterocyclic thio group having 2 to 30 carbon atoms, for example, 2-benzothiazolylthio or 1-phenyltetrazole-5-ylthio); a sulfamoyl group (preferably a substituted or unsubstituted sulfamoyl group having 0 to 30 carbon atoms, for example, N-ethylsulfamoyl, N-(3-dodecyloxypropyl) sulfamoyl, N,N-dimethylsulfamoyl, N-acetyl sulfamoyl, N-benzoylsulfamoyl, or N—(N′-phenylcarbamoyl) sulfamoyl); a sulfo group; alkyl and aryl sulfinyl groups (preferably a substituted or unsubstituted alkyl sulfinyl group having 1 to 30 carbon atoms, and a substituted or unsubstituted aryl sulfinyl group having 6 to 30 carbon atoms, for example, methylsulfinyl, ethylsulfinyl, phenylsulfinyl, or p-methyl phenylsulfinyl);
alkyl and aryl sulfonyl groups (preferably a substituted or unsubstituted alkyl sulfonyl group having 1 to 30 carbon atoms, and a substituted or unsubstituted aryl sulfonyl group having 6 to 30 carbon atoms, for example, methylsulfonyl, ethylsulfonyl, phenylsulfonyl, or p-methyl phenylsulfonyl); an acyl group (preferably, a formyl group, a substituted or unsubstituted alkylcarbonyl group having 2 to 30 carbon atoms, a substituted or unsubstituted arylcarbonyl group having 7 to 30 carbon atoms, and a substituted or unsubstituted heterocyclic carbonyl group having 4 to 30 carbon atoms in which a carbon atom is bonded with the carbonyl group, for example, acetyl, pivaloyl, 2-chloroacetyl, stearoyl, benzoyl, p-n-octyloxyphenyl carbonyl, 2-pyridylcarbonyl, or 2-furyl carbonyl); an aryloxycarbonyl group (preferably, a substituted or unsubstituted aryloxy carbonyl group having 7 to 30 carbon atoms, for example, phenoxycarbonyl, o-chlorophenoxycarbonyl, m-nitrophenoxycarbonyl, or p-t-butylphenoxycarbonyl); an alkoxycarbonyl group (preferably, a substituted or unsubstituted alkoxycarbonyl group having 2 to 30 carbon atoms, for example, methoxycarbonyl, ethoxycarbonyl, t-butoxycarbonyl, or n-octadecyl oxycarbonyl);
a carbamoyl group (preferably a substituted or unsubstituted carbamoyl having 1 to 30 carbon atoms, for example, carbamoyl, N-methylcarbamoyl, N,N-dimethylcarbamoyl, N,N-di-n-octylcarbamoyl, or N-(methylsulfonyl)carbamoyl); aryl and heterocyclic azo groups (preferably a substituted or unsubstituted aryl azo group having 6 to 30 carbon atoms, and a substituted or unsubstituted heterocyclic azo group having 3 to 30 carbon atoms, for example, phenylazo, p-chlorophenyl azo, or 5-ethylthio-1,3,4-thiadiazole-2-yl azo); an imide group (preferably, N-succinimide, no N-phthalimide); a phosphino group (preferably, a substituted or unsubstituted phosphino group having 2 to 30 carbon atoms, for example, dimethylphosphino, diphenylphosphino, or methylphenoxy phosphino); a phosphinyl group (preferably, a substituted or unsubstituted phosphinyl group having 2 to 30 carbon atoms, for example, phosphinyl, dioctyloxyphosphinyl, or diethoxyphosphinyl); a phosphinyloxy group (preferably, a substituted or unsubstituted phosphinyloxy group having 2 to 30 carbon atoms, for example, diphenoxyphosphinyloxy or dioctyloxyphosphinyloxy); a phosphinylamino group (preferably a substituted or unsubstituted phosphinylamino group having 2 to 30 carbon atoms, for example, dimethoxyphosphinylamino or dimethylamino phosphinylamino); and a silyl group (preferably a substituted or unsubstituted silyl group having 3 to 30 carbon atoms, for example, trimethylsilyl, t-butyldimethylsilyl, or phenyldimethylsilyl).

Among the above functional groups, functional groups having a hydrogen atom may be further substituted with the above groups by removing the hydrogen atom. Examples of such functional groups include an alkylcarbonylaminosulfonyl group, an arylcarbonylaminosulfonyl group, an alkylsulfonyl aminocarbonyl group, an arylsulfonyl aminocarbonyl group, and the like. Examples thereof include methylsulfonylaminocarbonyl, p-methylphenyl sulfonyl aminocarbonyl, acetylamino sulfonyl, benzoylaminosulfonyl group, and the like.

The alkenyl group represented by R₂ and R₃ is a linear, branched, or cyclic substituted or unsubstituted alkenyl group. The alkenyl group has preferably 2 to 50 carbon atoms, more preferably 2 to 30 carbon atoms, and particularly preferably 2 to 20 carbon atoms. Preferable examples thereof include vinyl, allyl, prenyl, geranyl, oleyl, 2-cyclopentene-1-yl, 2-cyclohexene-1-yl, bicyclo[2.2.1]hept-2-en-1-yl, bicyclo[2.2.2]oct-2-en-4-yl, and the like. More preferable examples thereof include vinyl, allyl, prenyl, geranyl, oleyl, 2-cyclopentene-1-yl, and 2-cyclohexene-1-yl.

The alkenyl group represented by R₂ and R₃ may further include a substituent. Examples of the substituent include the substituents of the above-mentioned alkyl group represented by R₂ and R₃.

In addition, similarly to the above-mentioned alkyl group, the alkenyl group may include a linking group such as —CO—, —NH—, —O—, —S—, or a group composed of any combination of these.

The alkynyl group represented by R₂ and R₃ is a linear, branched, or cyclic substituted or unsubstituted alkynyl group. The alkynyl group has preferably 2 to 50 carbon atoms, more preferably 2 to 30 carbon atoms, and particularly preferably 2 to 20 carbon atoms. Preferable examples thereof include ethynyl, propargyl, and the like.

The alkynyl group represented by R₂ and R₃ may further include a substituent. Examples of the substituent include the substituents of the above-mentioned alkyl group represented by R₂ and R₃.

In addition, similarly to the above-mentioned alkyl group, the alkynyl group may include a linking group such as —CO—, —NH—, —O—, —S—, or a group composed of any combination of these.

The aryl group represented by R₂ and R₃ is a substituted or unsubstituted aryl group. The aryl group has preferably 6 to 50 carbon atoms, more preferably 6 to 30 carbon atoms, and particularly preferably 6 to 20 carbon atoms. Preferable examples thereof include phenyl, 2-methylphenyl, 3-methylphenyl, 4-methylphenyl, 2-ethylphenyl, 4-ethylphenyl, 2,4-dimethylphenyl, 2,6-dimethylphenyl, 2,4,6-trimethylphenyl, 1-naphthyl, 2-naphthyl, 2-chlorophenyl, 3-chlorophenyl, 4-chlorophenyl, 2-methoxyphenyl, 3-methoxyphenyl, 4-methoxyphenyl, 2-benzylphenyl, 4-benzylphenyl, 2-methylcarbonylphenyl, 4-methylcarbonylphenyl, and the like.

More preferable examples thereof include phenyl, 2-methylphenyl, 4-methylphenyl, 2-ethylphenyl, 4-ethylphenyl, 2,4-dimethylphenyl, 2,6-dimethylphenyl, 2,4,6-trimethylphenyl, 1-naphthyl, 2-naphthyl, 2-chlorophenyl, 4-chlorophenyl, 2-methoxyphenyl, 3-methoxyphenyl, 4-methoxyphenyl, 2-benzylphenyl, 4-benzylphenyl, and the like. Particularly preferable examples thereof include phenyl, 2-methylphenyl, 4-methylphenyl, 2,4-dimethylphenyl, 2,6-dimethylphenyl, 2,4,6-trimethylphenyl, 1-naphthyl, 2-naphthyl, 2-chlorophenyl, 4-chlorophenyl, 2-methoxyphenyl, 4-methoxyphenyl, 2-benzylphenyl, 4-benzylphenyl, and the like.

The aryl group represented by R₂ and R₃ may further include a substituent. Examples of the substituent include the substituents of the above-mentioned alkyl group represented by R₂ and R₃.

Each of R₄ and R₅ independently represents a hydrogen atom or a substituent.

Examples of the substituents represented by R₄ and R₅ may include the substituents of the above-mentioned alkyl group represented by R₂ and R₃ (the substituents which the alkyl group may have). Preferable examples thereof include an alkyl group, an alkenyl group, an alkynyl group, an aryl group, and a group composed of any combination of these, and preferable examples of the respective groups include the examples of the above-mentioned R₂ and R₃.

The group represented by R₄ and R₅ may further include a substituent. Examples of the substituent include the substituents of the above-mentioned alkyl group represented by R₂ and R₃.

Each of R₁ and R₆ independently represents a hydrogen atom or a substituent.

Examples of the substituents represented by R₁ and R₆ may include the substituents of the above-mentioned alkyl group represented by R₂ and R₃. Preferable examples thereof include an alkyl group, an alkenyl group, an alkynyl group, an aryl group, and a group composed of any combination of these, and preferable examples of the respective groups include the examples of above-mentioned R₂ and R₃.

The group represented by R₁ and R₆ may further include a substituent. Examples of the substituent include the substituents of the above-mentioned alkyl group represented by R₂ and R₃.

n is an integer of 0 to 5. However, when n is 0, neither both P and Q are OH, nor both P and Q are CHR₄R₅. When n is 2 or more, a plurality of atomic groups represented by (CR₁═Y) may be the same as or different from each other.

The compound represented by General Formula (1) may be a chain compound or a cyclic compound. When the compound is a cyclic compound, at least two of groups represented by R₁, R₂, R₃, R₄, R₅, and R₆ may be bonded to each other to form a ring.

When the two groups are bonded to each other, the coupling form may be any of a single bond, a double bond, and a triple bond.

At least one group of R₁ to R₆ contains a fluorine atom. Here, the fluorine atom is contained such that the content rate thereof is within the aforementioned range. The fluorine atom may substitute for any carbon atom of the compound represented by the General Formula (1).

Further, it is preferable that some or all hydrogen atoms contained in at least one group of R₁ to R₆ (preferably, some or all hydrogen atoms bonded to carbon atoms) are substituted with fluorine atoms. Especially, it is preferable that fluorine atoms are contained as a fluoroalkyl group (hereinafter, referred to as an R_{f} group) or a group substituted with the R_{f} group. In other words, it is preferable that a fluoroalkyl group is contained in at least one group of R₁ to R₆.

It is preferable for the R_{f} group to be a linear or branched perfluoroalkyl group having 1 to 14 carbon atoms or a substituent having 2 to 20 carbon atoms and substituted with the linear or branched perfluoroalkyl group having 1 to 14 carbon atoms.

Examples of the linear or branched perfluoroalkyl group having 1 to 14 carbon atoms include CF₃—, C₂F₅—, C₃F₇—, C₄F₉—, C₅F₁₁—, (CF₃)₂—CF—(CF₂)₂—, C₆F₁₃—, C₇F₁₅—, (CF₃)₂—CF—(CF₂)₄—, C₈F₁₇—, C₉F₁₉—, C₁₀F₂₁—, C₁₂F₂₅—, and C₁₄F₂₉—.

Examples of the substituent having 2 to 20 carbon atoms and substituted with the linear or branched perfluoroalkyl group having 1 to 14 carbon atoms include, but are not limited to, (CF₃)₂CF(CF₂)₄(CH₂)₂—, C₉F₁₉CH₂—, C₈F₁₇CH₂CH(OH)CH₂—, C₈F₁₇CH₂CH(OH)CH₂OC═OCH₂—, (CF₃)₂CF(CF₂)₄(CH₂)₂OC═OCH₂—, C₈F₁₇CH₂CH(OH)CH₂OC═O (CH₂)₂—, (CF₃)₂CF(CF₂)₄(CH₂)₂OC═O (CH₂)₂—, (CF₃)₂CFOC₂F₄—, and CF₃CF₂CF₂O[CF(CF₃) CF₂O]₄—CF(CF₃)—.

It is preferable that 1 to 4 R_{f} groups are contained in a molecule.

Two or more kinds of the compound represented by the General Formula (1) may be used.

It is preferable that the compound represented by General Formula (1) is at least one selected from the group consisting of compounds represented by General Formulae (6) to (21).

Each of compounds represented by General Formulae (6) to (21) contains fluorine atoms in an amount of satisfying the above-mentioned fluorine content rate.

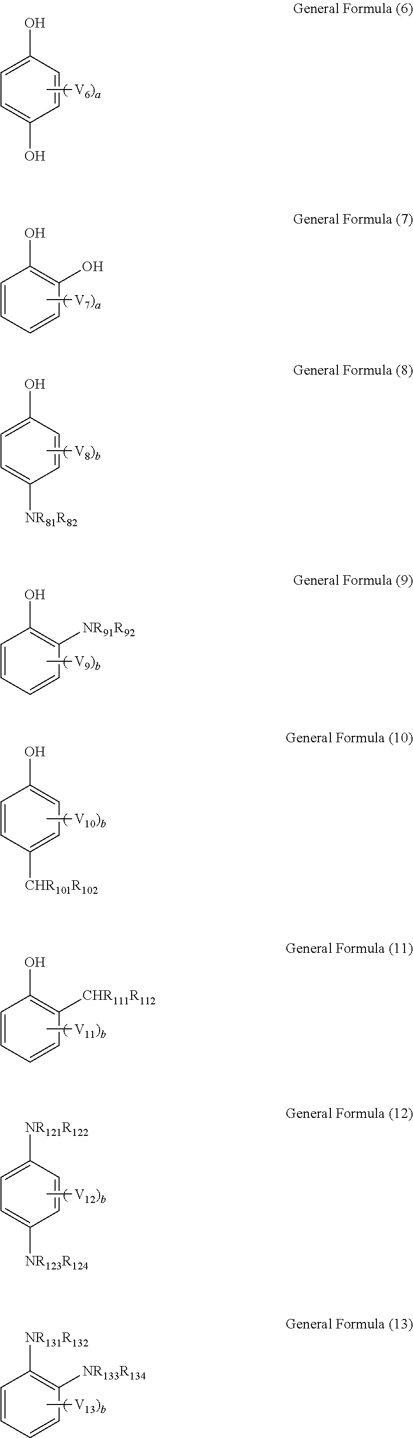

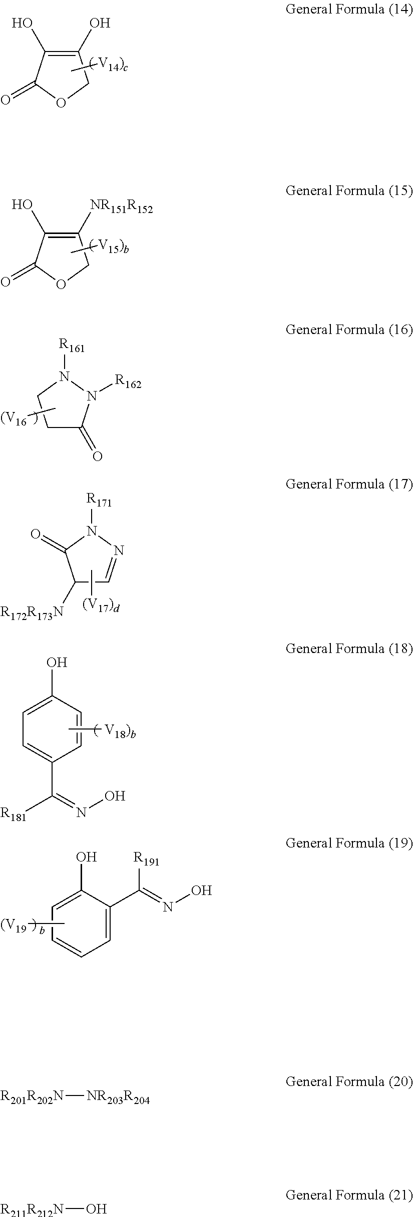

The compound represented by the General Formula (6) is an example of the compound of General Formula (1) in which P and Q are OH respectively, Y is CR₆, n is 2, and R₁ on the carbon atom adjacent to P and R₆ on the carbon atom adjacent to Q are bonded to each other to form a ring having a double bond.

In the General Formula (6), V₆ represents a substituent. a is an integer of 1 to 4 (preferably 1 to 2, and more preferably 1). At least one of V₆ contains a fluorine atom. In other words, in the case of one V₆, the fluorine atom is contained in the substituent, and, in the case of two or more V₆, the fluorine atom may be contained in at least one V₆. It is preferable that fluorine atoms are introduced by substituting some or all hydrogen atoms of at least one group represented by V₆ (preferably, some or all hydrogen atoms bonded to carbon atoms) with the fluorine atoms. In this case, it is preferable that the above R_{f} group is contained in V₆.

As the substituent represented by V₆, there can be exemplified the substituents of the above-mentioned alkyl group represented by R₂ and R₃ in the General Formula (1). When a plurality of V₆ are present in the General Formula (6), the respective groups may be the same as or different from each other, and may be bonded to each other to form a ring.

Specific examples of the compound represented by the General Formula (6) are shown below. However, the present invention is not limited thereto. Hereinafter, the percentage described with the structural formula of each of the compounds is intended to represent the mass content rate of fluorine atoms (fluorine content rate).

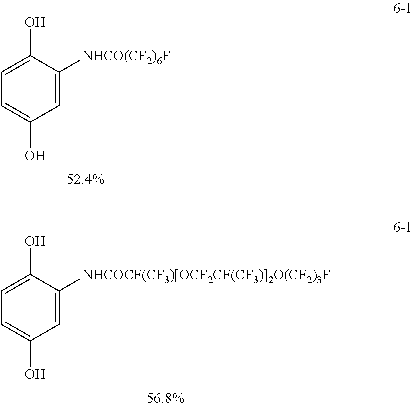

The compound represented by the General Formula (7) is an example of the compound of General Formula (1) in which P and Q are OH respectively, Y is CR₆, n is 1, and R₁ on the carbon atom adjacent to P and R₆ on the carbon atom adjacent to Q are bonded to each other to form a ring.

In the General Formula (7), V₇ represents a substituent. a is an integer of 1 to 4 (preferably 1 to 2, and more preferably 1). At least one V₇ contains a fluorine atom. In other words, in the case of one V₇, the fluorine atom is contained in the substituent, and, in the case of two or more V₇, the fluorine atom may be contained in at least one V₇. It is preferable that fluorine atoms are introduced by substituting some or all hydrogen atoms of at least one group represented by V₇ (preferably, some or all hydrogen atoms bonded to carbon atoms) with the fluorine atoms. In this case, it is preferable that the above R_{f} group is contained in V₇.

As the substituent represented by V₇, there can be exemplified the substituents of the above-mentioned alkyl group represented by R₂ and R₃ in the General Formula (1). When a plurality of V₇ are present in the General Formula (7), the respective groups may be the same as or different from each other, and may be bonded to each other to form a ring.

Specific examples of the compound represented by the General Formula (7) are shown below. However, the present invention is not limited thereto.

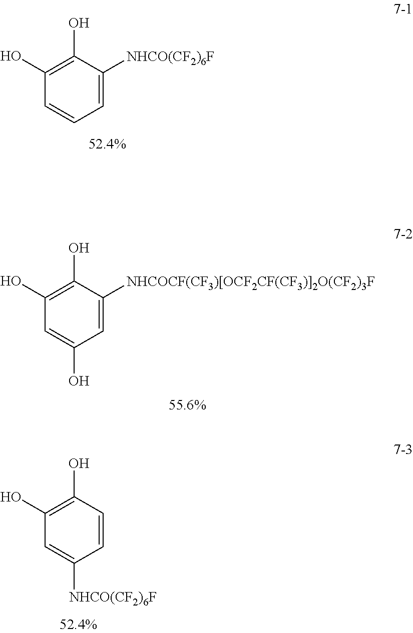

The compound represented by the General Formula (8) is an example of the compound of General Formula (1) in which P is OH, Q is NR₂R₃, Y is CR₆, n is 2, and R₁ on the carbon atom adjacent to P and R₆ on the carbon atom adjacent to Q are bonded to each other to form a ring having a double bond.

In the General Formula (8), V₈ represents a substituent. b is an integer of 0 to 4 (preferably 1 to 2, and more preferably 1). As the substituent represented by V₈, there can be exemplified the substituents of the above-mentioned alkyl group represented by R₂ and R₃ in the General Formula (1). When a plurality of V₈ are present in the General Formula (8), the respective groups may be the same as or different from each other, and may be bonded to each other to form a ring.

Each of R₈₁ and R₈₂ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₈, R₈₁, and R₈₂ contains a fluorine atom. Especially, it is preferable that some or all hydrogen atoms of at least one group of V₈, R₈₁, and R₈₂ (preferably, some or all hydrogen atoms bonded to carbon atoms) are substituted with fluorine atoms. In addition, it is more preferable that the above R_{f} group is contained in at least one of V₈, R₈₁, and R₈₂.

Further, in the case where a plurality of V₈ is contained in the compound, the fluorine atom is contained in at least one group of the plurality of V₈, R₈₁, and R₈₂.

Specific examples of the compound represented by the General Formula (8) are shown below. However, the present invention is not limited thereto.

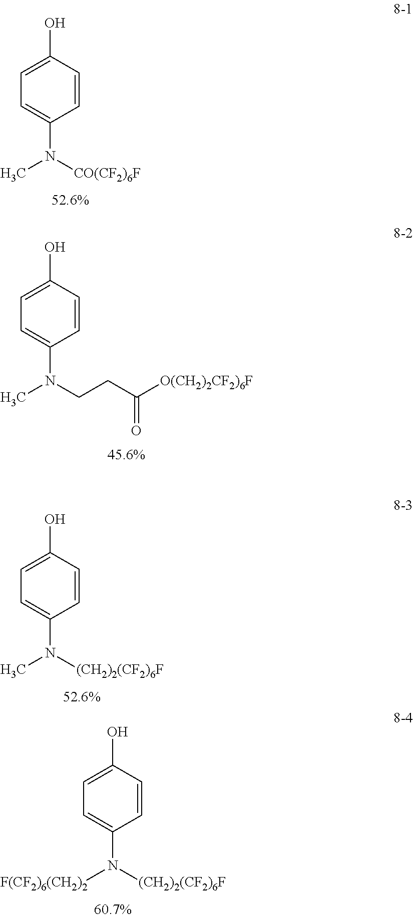

The compound represented by the General Formula (9) is an example of the compound of General Formula (1) in which P is OH, Q is NR₂R₃, Y is CR₆, n is 1, and R₁ on the carbon atom adjacent to P and R₆ on the carbon atom adjacent to Q are bonded to each other to form a ring.

In the General Formula (9), V₉ represents a substituent. b is an integer of 0 to 4 (preferably 1 to 2, and more preferably 1). As the substituent represented by V₉, there can be exemplified the substituents of the above-mentioned alkyl group represented by R₂ and R₃ in the General Formula (1). When a plurality of V₉ are present in the General Formula (9), the respective groups may be the same as or different from each other, and may be bonded to each other to form a ring.

Each of R₉₁ and R₉₂ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₉, R₉₁, and R₉₂ contains a fluorine atom. Especially, it is preferable that some or all hydrogen atoms of at least one group of V₉, R₉₁, and R₉₂ (preferably, some or all hydrogen atoms bonded to carbon atoms) are substituted with fluorine atoms. In addition, it is more preferable that the above R_{f} group is contained in at least one of V₉, R₉₁, and R₉₂.

Further, in the case where a plurality of V₉ is contained in the compound, the fluorine atom is contained in at least one group of the plurality of V₉, R₉₁, and R₉₂.

Specific examples of the compound represented by the General Formula (9) are shown below. However, the present invention is not limited thereto.

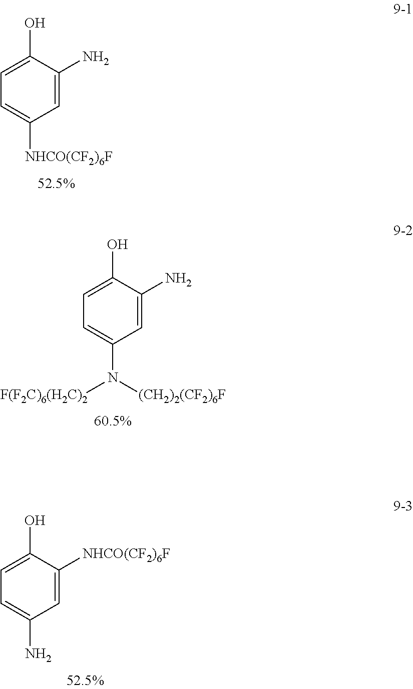

The compound represented by the General Formula (10) is an example of the compound of General Formula (1) in which P is OH, Q is CHR₄R₅, Y is CR₆, n is 2, and R₁ on the carbon atom adjacent to P and R₆ on the carbon atom adjacent to Q are bonded to each other to form a ring having a double bond.

In the General Formula (10), V₁₀ represents a substituent. b is an integer of 0 to 4 (preferably 1 to 2, and more preferably 1). As the substituent represented by V₁₀, there can be exemplified the substituents of the above-mentioned alkyl group represented by R₂ and R₃ in the General Formula (1). When a plurality of V₁₀ are present in the General Formula (10), the respective groups may be the same as or different from each other, and may be bonded to each other to form a ring.

Each of R₁₀₁ and R₁₀₂ independently represents a hydrogen atom or a substituent.

As the substituent represented by R₁₀₁ and R₁₀₂, there can be exemplified the substituents of the above-mentioned alkyl group represented by R₂ and R₃. The substituent is preferably an alkyl group, an alkenyl group, an alkynyl group, or an aryl group. Preferable examples of the respective groups include the examples of the above-mentioned R₂ and R₃.

When R₁₀₁ and R₁₀₂ are substituents, each of these groups may further include a substituent. Examples of the substituent include the substituents of the above-mentioned alkyl group represented by R₂ and R₃ in the General Formula (1).

At least one of V₁₀, R₁₀₁, and R₁₀₂ contains a fluorine atom. Especially, it is preferable that some or all hydrogen atoms of at least one group of V₁₀, R₁₀₁, and R₁₀₂ (preferably, some or all hydrogen atoms bonded to carbon atoms) are substituted with fluorine atoms. In addition, it is preferable that the above R_{f} group is contained in at least one of V₁₀, R₁₀₁, and R₁₀₂.

Further, in the case where a plurality of V₁₀ is contained in the compound, the fluorine atom is contained in at least one group of the plurality of V₁₀, R₁₀₁, and R₁₀₂.

Specific examples of the compound represented by the General Formula (10) are shown below. However, the present invention is not limited thereto.

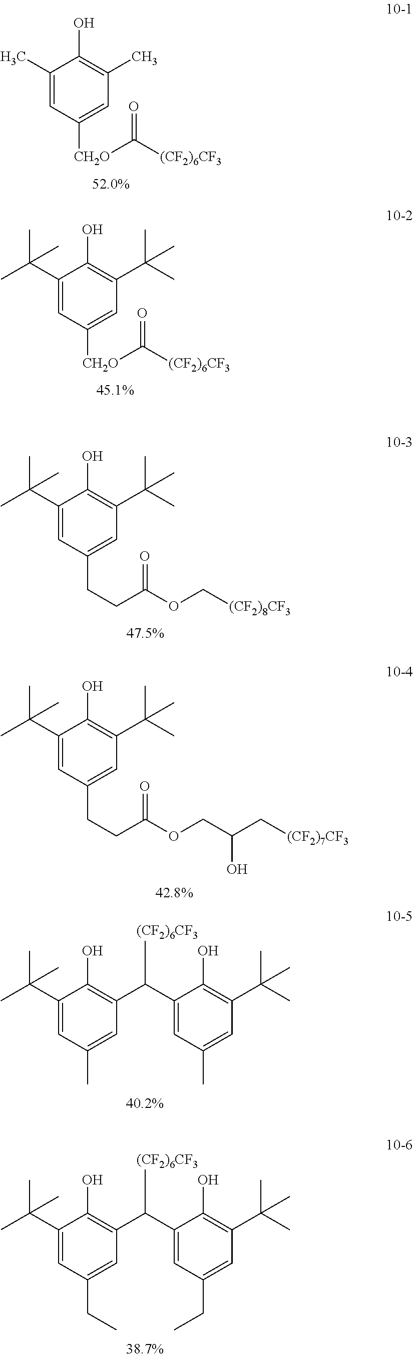

The compound represented by the General Formula (11) is an example of the compound of General Formula (1) in which P is OH, Q is CHR₄R₅, Y is CR₆, n is 1, and R₁ on the carbon atom adjacent to P and R₆ on the carbon atom adjacent to Q are bonded to each other to form a ring.

In the General Formula (11), V₁₁ represents a substituent. b is an integer of 0 to 4 (preferably 1 to 2, and more preferably 1). As the substituent represented by V₁₁, there can be exemplified the substituents of the above-mentioned alkyl group represented by R₂ and R₃ in the General Formula (1). When a plurality of V₁₁ are present in the General Formula (11), the respective groups may be the same as or different from each other, and may be bonded to each other to form a ring.

Each of R₁₁₁ and R₁₁₂ independently represents a hydrogen atom or a substituent.

As the substituent represented by R₁₁₁ and R₁₁₂, there can be exemplified the substituents of the above-mentioned alkyl group represented by R₂ and R₃. The substituent is preferably an alkyl group, an alkenyl group, an alkynyl group, or an aryl group. Preferable examples of the respective groups include the examples of the above-mentioned R₂ and R₃.

When R₁₁₁ and R₁₁₂ are substituents, each of these groups may further include a substituent. Examples of the substituent include the substituents of the above-mentioned alkyl group represented by R₂ and R₃ in the General Formula (1).

At least one of V₁₁, R₁₁₁, and R₁₁₂ contains a fluorine atom. Especially, it is preferable that some or all hydrogen atoms of at least one group of V₁₁, R₁₁₁, and R₁₁₂ (preferably, some or all hydrogen atoms bonded to carbon atoms) are substituted with fluorine atoms. In addition, it is preferable that the above R_{f} group is contained in at least one of V₁₁, R₁₁₁, and R₁₁₂.

Further, in the case where a plurality of V₁₁ is contained in the compound, the fluorine atom is contained in at least one group of the plurality of V₁₁, R₁₁₁, and R₁₁₂.

Specific examples of the compound represented by the General Formula (11) are shown below. However, the present invention is not limited thereto.

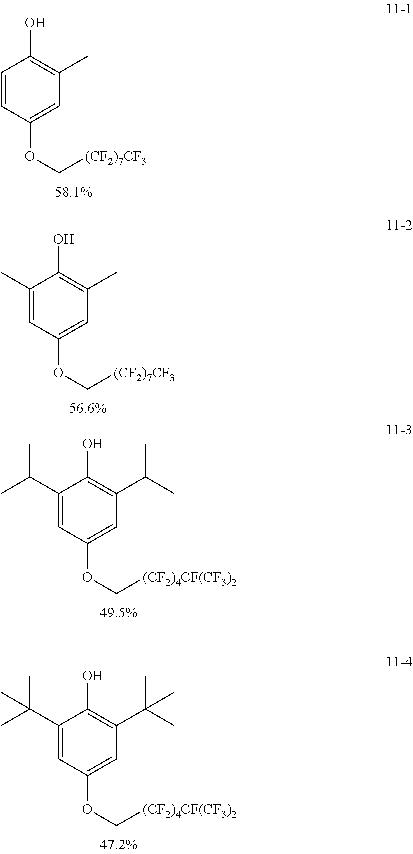

The compound represented by the General Formula (12) is an example of the compound of General Formula (1) in which P and Q are NR₂R₃ respectively, Y is CR₆, n is 2, and R₁ on the carbon atom adjacent to P and R₆ on the carbon atom adjacent to Q are bonded to each other to form a ring having a double bond.

In the General Formula (12), V₁₂ represents a substituent. b is an integer of 0 to 4 (preferably 1 to 2, and more preferably 1). As the substituent represented by V₁₂, there can be exemplified the substituents of the above-mentioned alkyl group represented by R₂ and R₃ in the General Formula (1). When a plurality of V₁₂ are present in the General Formula (12), the respective groups may be the same as or different from each other, and may be bonded to each other to form a ring.

Each of R₁₂₁, R₁₂₂, R₁₂₃, and R₁₂₄ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₁₂, R₁₂₁, R₁₂₂, R₁₂₃, and R₁₂₄ contains a fluorine atom. In this case, it is preferable that some or all hydrogen atoms of at least one group of V₁₂, R₁₂₁, R₁₂₂, R₁₂₃, and R₁₂₄ (preferably, some or all hydrogen atoms bonded to carbon atoms) are substituted with fluorine atoms. In addition, it is more preferable that the above R_{f} group is contained in at least one of V₁₂, R₁₂₁, R₁₂₂, R₁₂₃, and R₁₂₄.

Further, in the case where a plurality of V₁₂ is contained in the compound, the fluorine atom is contained in at least one group of the plurality of V₁₂, R₁₂₁, R₁₂₂, R₁₂₃, and R₁₂₄.

Specific examples of the compound represented by the General Formula (12) are shown below. However, the present invention is not limited thereto.

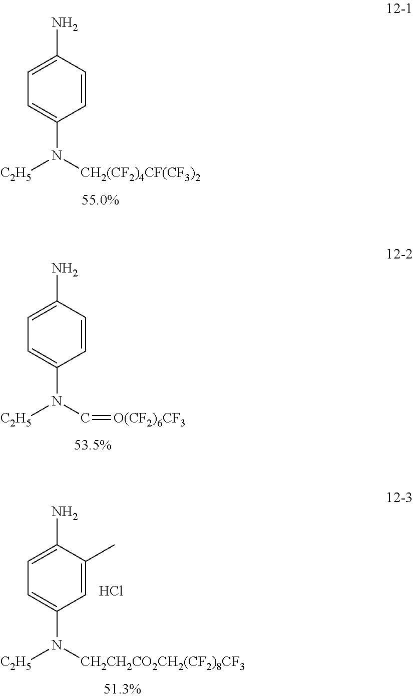

The compound represented by the General Formula (13) is an example of the compound of General Formula (1) in which P and Q are NR₂R₃ respectively, Y is CR₆, n is 1, and R₁ on the carbon atom adjacent to P and R₆ on the carbon atom adjacent to Q are bonded to each other to form a ring.

In the General Formula (13), V₁₃ represents a substituent. b is an integer of 0 to 4 (preferably 1 to 2, and more preferably 1). As the substituent represented by V₁₃, there can be exemplified the substituents of the above-mentioned alkyl group represented by R₂ and R₃ in the General Formula (1). When a plurality of V₁₃ are present in the General Formula (13), the respective groups may be the same as or different from each other, and may be bonded to each other to form a ring.

Each of R₁₃₁, R₁₃₂, R₁₃₃, and R₁₃₄ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₁₃, R₁₃₁, R₁₃₂, R₁₃₃, and R₁₃₄ contains a fluorine atom. In this case, it is preferable that some or all hydrogen atoms of at least one group of V₁₃, R₁₃₁, R₁₃₂, R₁₃₃, and R₁₃₄ (preferably, some or all hydrogen atoms bonded to carbon atoms) are substituted with fluorine atoms. In addition, it is more preferable that the above R_{f} group is contained in at least one of V₁₃, R₁₃₁, R₁₃₂, R₁₃₃, and R₁₃₄.

Further, in the case where a plurality of V₁₃ is contained in the compound, the fluorine atom is contained in at least one group of the plurality of V₁₃, R₁₃₁, R₁₃₂, R₁₃₃, and R₁₃₄.

Specific examples of the compound represented by the General Formula (13) are shown below. However, the present invention is not limited thereto.

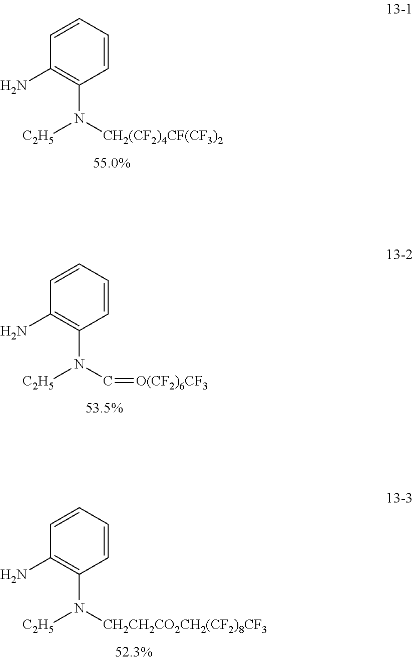

The compound represented by the General Formula (14) is an example of the compound of General Formula (1) in which P and Q are OH respectively, Y is CR₆, n is 1, and R₁ on the carbon atom adjacent to P and R₆ on the carbon atom adjacent to Q are bonded to each other to form a ring.

In the General Formula (14), V₁₄ represents a substituent. c is an integer of 1 to 2 (preferably 1). At least one V₁₄ contains a fluorine atom. In other words, in the case of one V₁₄, the fluorine atom is contained in the substituent, and, in the case of two or more V₁₄, the fluorine atom may be contained in at least one V₁₄. It is preferable that fluorine atoms are introduced by substituting some or all hydrogen atoms of at least one group represented by V₁₄ (preferably, some or all hydrogen atoms bonded to carbon atoms) with the fluorine atoms. In this case, it is more preferable that the above R_{f} group is contained in V₁₄.

As the substituent represented by V₁₄, there is exemplified the substituents of the above-mentioned alkyl group represented by R₂ and R₃ in the General Formula (1). When a plurality of V₁₄ are present in the General Formula (14), the respective groups may be the same as or different from each other, and may be bonded to each other to form a ring.

Specific examples of the compound represented by the General Formula (14) are shown below. However, the present invention is not limited thereto.

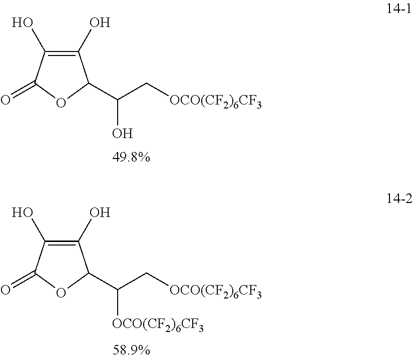

The compound represented by the General Formula (15) is an example of the compound of General Formula (1) in which P is OH, Q is NR₂R₃, Y is CR₆, n is 1, and R₁ on the carbon atom adjacent to P and R₆ on the carbon atom adjacent to Q are bonded to each other to form a ring.

In the General Formula (15), V₁₅ represents a substituent. b is an integer of 0 to 4 (preferably, 1 to 2, and more preferably 1). As the substituent represented by V₁₅, there can be exemplified the substituents of the above-mentioned alkyl group represented by R₂ and R₃ in the General Formula (1). When a plurality of V₁₅ are present in the General Formula (15), the respective groups may be the same as or different from each other, and may be bonded to each other to form a ring.

Each of R₁₅₁ and R₁₅₂ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₁₅, R₁₅₁, and R₁₅₂ contains a fluorine atom. Especially, it is preferable that some or all hydrogen atoms of at least one group of V₁₅, R₁₅₁, and R₁₅₂ (preferably, some or all hydrogen atoms bonded to carbon atoms) are substituted with fluorine atoms. In addition, it is preferable that the above R_{f} group is contained in at least one of V₁₅, R₁₅₁, and R₁₅₂.

Further, in the case where a plurality of V₁₅ is contained in the compound, the fluorine atom is contained in at least one group of the plurality of V₁₅, R₁₅₁, and R₁₅₂.

Specific examples of the compound represented by the General Formula (15) are shown below. However, the present invention is not limited thereto.

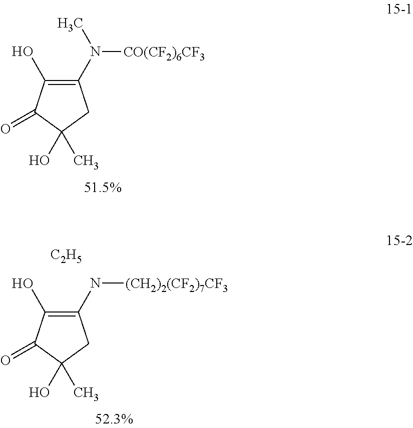

The compound represented by the General Formula (16) is an example of the compound of General Formula (1) in which P and Q are NR₂R₃ respectively, n is 0, and R₂ and R₃ are bonded to each other to form a ring.

In the General Formula (16), V₁₆ represents a substituent. b is an integer of 0 to 4 (preferably, 1 to 2, and more preferably 1). As the substituent represented by V₁₆, there can be exemplified the substituents of the above-mentioned alkyl group represented by R₂ and R₃ in the General Formula (1). When a plurality of V₁₆ are present in the General Formula (16), the respective groups may be the same as or different from each other, and may be bonded to each other to form a ring.

Each of R₁₆₁ and R₁₆₂ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₁₆, R₁₆₁, and R₁₆₂ contains a fluorine atom. Especially, it is preferable that some or all hydrogen atoms of at least one group of V₁₆, R₁₆₁, and R₁₆₂ (preferably, some or all hydrogen atoms bonded to carbon atoms) are substituted with fluorine atoms. In addition, it is preferable that the above R_{f} group is contained in at least one of V₁₆, R₁₆₁, and R₁₆₂.

Further, in the case where a plurality of V₁₆ is contained in the compound, the fluorine atom is contained in at least one group of the plurality of V₁₆, R₁₆₁, and R₁₆₂.

Specific examples of the compound represented by the General Formula (16) are shown below. However, the present invention is not limited thereto.

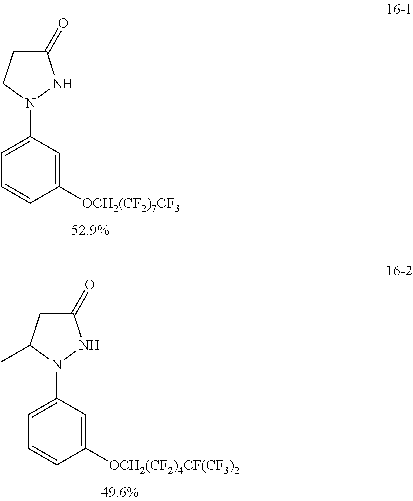

The compound represented by the General Formula (17) is an example of the compound of General Formula (1) in which P and Q are NR₂R₃ respectively, n is 0, and R₂ and R₃ are bonded to each other to form a ring.

In the General Formula (17), V₁₇ represents a substituent. d is 0 or 1. As the substituent represented by V₁₇, there can be exemplified the substituents of the above-mentioned alkyl group represented by R₂ and R₃ in the General Formula (1). When a plurality of V₁₇ are present in the General Formula (17), the respective groups may be the same as or different from each other, and may be bonded to each other to form a ring.

Each of R₁₇₁, R₁₇₂, and R₁₇₃ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of V₁₇, R₁₇₁, R₁₇₂, and R₁₇₃ contains a fluorine atom. Especially, it is preferable that some or all hydrogen atoms of at least one group of V₁₇, R₁₇₁, R₁₇₂, and R₁₇₃ (preferably, some or all hydrogen atoms bonded to carbon atoms) are substituted with fluorine atoms. In addition, it is preferable that the above R_{f} group is contained in at least one of V₁₇, R₁₇₁, R₁₇₂, and R₁₇₃.

Further, in the case where a plurality of V₁₇ is contained in the compound, the fluorine atom is contained in at least one group of the plurality of V₁₇, R₁₇₁, R₁₇₂, and R₁₇₃.

Specific examples of the compound represented by the General Formula (17) are shown below. However, the present invention is not limited thereto.

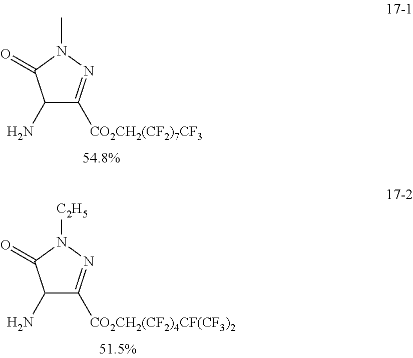

The compound represented by the General Formula (18) is an example of the compound of General Formula (1) in which P and Q are OH respectively, Y is CR₆ and nitrogen atom, n is 3, and R₁ and R₆ are bonded to each other to form a ring.

In the General Formula (18), V₁₈ represents a substituent. b is an integer of 0 to 4 (preferably 1 to 2, and more preferably 1). As the substituent represented by V₁₈, there can be exemplified the substituents of the above-mentioned alkyl group represented by R₂ and R₃ in the General Formula (1). When a plurality of V₁₈ are present in the General Formula (18), the respective groups may be the same as or different from each other, and may be bonded to each other to form a ring.

R₁₈₁ represents a hydrogen atom or a substituent. As the substituent represented by R₁₈₁, there can be exemplified the substituents of the above-mentioned alkyl group represented by R₂ and R₃. The substituent is preferably an alkyl group, an alkenyl group, an alkynyl group, or an aryl group. Preferable examples of the respective groups include the examples of the above-mentioned R₂ and R₃.

When R₁₈₁ represents a substituent, this group may further include a substituent. Examples of the substituent include the substituents of the above-mentioned alkyl group represented by R₂ and R₃ in the General Formula (1).

At least one of V₁₈ and R₁₈₁ contains a fluorine atom. Especially, it is preferable that some or all hydrogen atoms of at least one group of V₁₈ and R₁₈₁ (preferably, some or all hydrogen atoms bonded to carbon atoms) are substituted with fluorine atoms. In addition, it is preferable that the above R_{f} group is contained in at least one of V₁₈ and R₁₈₁.

Further, in the case where a plurality of V₁₈ is contained in the compound, the fluorine atom is contained in at least one group of the plurality of V₁₈ and R₁₈₁.

Specific examples of the compound represented by the General Formula (18) are shown below. However, the present invention is not limited thereto.

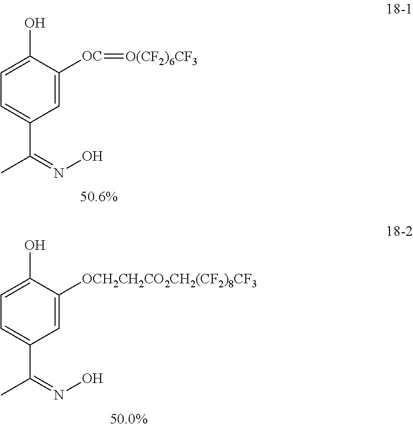

The compound represented by the General Formula (19) is an example of the compound of General Formula (1) in which P and Q are OH respectively, Y is CR₆ and nitrogen atom, n is 2, and R₁ and R₆ are bonded to each other to form a ring.

In the General Formula (19), V₁₉ represents a substituent. b is an integer of 0 to 4 (preferably 1 to 2, and more preferably 1). As the substituent represented by V₁₉, there can be exemplified the substituents of the above-mentioned alkyl group represented by R₂ and R₃ in the General Formula (1). When a plurality of V₁₉ are present in the General Formula (19), the respective groups may be the same as or different from each other, and may be bonded to each other to form a ring.

R₁₉₁ represents a hydrogen atom or a substituent. As the substituent represented by R₁₉₁, there can be exemplified the substituents of the above-mentioned alkyl group represented by R₂ and R₃. The substituent is preferably an alkyl group, an alkenyl group, an alkynyl group, or an aryl group. Preferable examples of the respective groups include the examples of the above-mentioned R₂ and R₃.

When R₁₉₁ represents a substituent, this group may further include a substituent. Examples of the substituent include the substituents of the above-mentioned alkyl group represented by R₂ and R₃ in the General Formula (1).

At least one of V₁₉ and R₁₉₁ contains a fluorine atom. In this case, it is preferable that some or all hydrogen atoms of at least one group of V₁₉ and R₁₉₁ (preferably, some or all hydrogen atoms bonded to carbon atoms) are substituted with fluorine atoms. In addition, it is preferable that the above R_{f} group is contained in at least one of V₁₉ and R₁₉₁.

Further, in the case where a plurality of V₁₉ is contained in the compound, the fluorine atom is contained in at least one group of the plurality of V₁₉ and R₁₉₁.

Specific examples of the compound represented by the General Formula (19) are shown below. However, the present invention is not limited thereto.

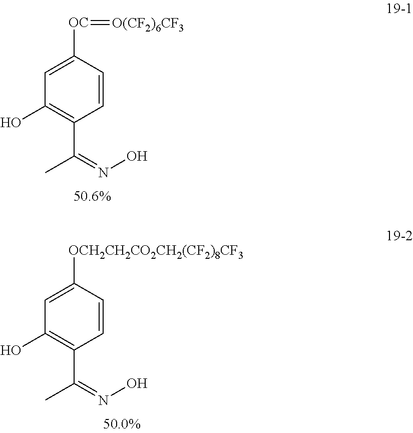

The compound represented by the General Formula (20) is an example of the compound of General Formula (1) in which P and Q are NR₂R₃ respectively, and n is 0.

In the General Formula (20), each of R₂₀₁, R₂₀₂, R₂₀₃, and R₂₀₄ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of R₂₀₁, R₂₀₂, R₂₀₃, and R₂₀₄ contains a fluorine atom. Especially, it is preferable that some or all hydrogen atoms of at least one group of R₂₀₁, R₂₀₂, R₂₀₃, and R₂₀₄ (preferably, some or all hydrogen atoms bonded to carbon atoms) are substituted with fluorine atoms. In addition, it is preferable that the above R_{f} group is contained in at least one of R₂₀₁, R₂₀₂, R₂₀₃, and R₂₀₄.

Specific examples of the compound represented by the General Formula (20) are shown below. However, the present invention is not limited thereto.

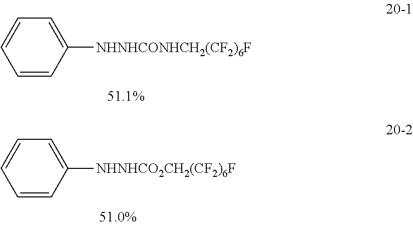

The compound represented by the General Formula (21) is an example of the compound of General Formula (1) in which P is NR₂R₃, Q is OH, and n is 0.

In the General Formula (21), each of R₂₁₁ and R₂₁₂ independently represents a hydrogen atom or a group which can be substituted with a nitrogen atom. Preferable examples of the group which can be substituted with a nitrogen atom include the groups exemplified in the above-mentioned R₂ and R₃ of the General Formula (1).

At least one of R₂₁₁ and R₂₁₂ contains a fluorine atom. Especially, it is preferable that some or all hydrogen atoms of at least one group of R₂₁₁ and R₂₁₂ (preferably, some or all hydrogen atoms bonded to carbon atoms) are substituted with fluorine atoms. In addition, it is preferable that the above R_{f} group is contained in at least one of R₂₁₁ and R₂₁₂.

Specific examples of the compound represented by the General Formula (21) are shown below. However, the present invention is not limited thereto.

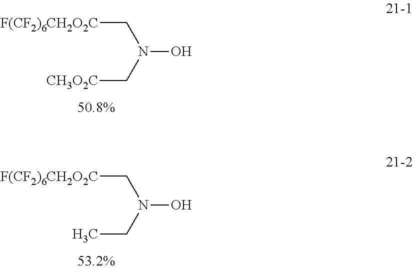

Meanwhile, as the most preferred embodiment of the compound represented by the General Formula (1), there is exemplified a compound represented by General Formula (X) below.

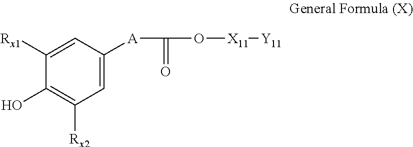

Each of Rₓ₁ and Rₓ₂ independently represents an alkyl group having 1 to 12 carbon atoms. From the viewpoints that the compatibility of the compound with the fluorine-based resin is more excellent and the ion migration-inhibiting ability of the sealing layer (sealing film) formed from the sealing resin composition is more excellent, the number of carbon atoms in the alkyl group is preferably 1 to 8, more preferably 1 to 6, and particularly preferably 1 to 5. Specific examples of the preferable alkyl group include methyl, ethyl, n-propyl, isopropyl, t-butyl, isobutyl, 2,2-dimethyl propyl, hexyl, cyclohexyl, and the like.

A represents an alkylene group having 1 to 2 carbon atoms. A is preferably —CH₂— or —CH₂CH₂—, and more preferably —CH₂CH₂—.

X₁₁ represents an alkylene group having 1 to 3 carbon atoms which may contain a hydroxyl group. X₁₁ is preferably —CH₂—, —CH₂CH₂—, —CH₂CH(CH₃)—, —CH₂CH₂CH₂—, —CH₂CH(OH)CH₂— or —CH₂CH(CH₂OH)—, more preferably —CH₂—, —CH₂CH₂—, —CH₂CH(OH)CH₂— or —CH₂CH₂CH₂—, and particularly preferably —CH₂— or —CH₂CH₂—.

Y₁₁ represents a linear perfluoroalkyl group having 4 to 12 carbon atoms. Preferred examples of the perfluoroalkyl group include C₄F₉—, C₅F₁₁—, C₆F₁₃—, C₇F₁₅—, C₈F₁₇—, C₉F₁₉—, C₁₀F₂₁—, and C₁₂F₂₅—. When the number of carbon atoms is within the above range, the compatibility of the compound with the fluorine-based resin is more excellent, and the ion migration-inhibiting ability of the sealing layer (sealing film) formed from the sealing resin composition is more excellent.

Rₓ₁, Rₓ₂, A, and X₁₁ may have the above-mentioned substituent.

(Compound Represented by General Formula (2))

Next, a compound represented by General Formula (2) will be described.

R₇—C(═O)—H General Formula (2)

In the present invention, the compound represented by the General Formula (2) also contains a compound exhibiting reducing properties due to the existence of equilibrium between aldehyde and hemiacetal (aldose or the like), or a compound forming aldehyde due to the isomerization between aldose and ketose by the L'Obree-Doburyuin-Fanedge Ken Stein dislocation reaction (fructose or the like).

In the General Formula (2), R₇ represents an alkyl group, an alkenyl group, an alkynyl group, an aryl group, a heterocyclic group, or a group composed of any combination of these.

When R₇ represents an alkyl group, an alkenyl group, an alkynyl group, or an aryl group, preferred examples of the respective groups include the examples of the above-mentioned R₂ and R₃.

When R₇ represents a heterocyclic group, R₇ is preferably a monovalent group obtained by removing one hydrogen atom from a 5- or 6-membered substituted or unsubstituted aromatic or non-aromatic heterocyclic compound, and more preferably a 5- or 6-membered aromatic or non-aromatic heterocyclic group having 3 to 30 carbon atoms. Preferred examples thereof include 2-furanyl, 2-thienyl, 2-pyrimidinyl, 2-benzothiazolyl, 2-benzoxazolyl, 2-imidazolyl, 4-imidazolyl, triazolyl, benzotriazolyl, thiadiazolyl, pyrrolidinyl, piperidinyl, imidazolidinyl, pyrazolidinyl, morpholinyl, tetrahydrofuranyl, tetrahydrothienyl, and the like.

R₇ is more preferably an alkyl group, an alkenyl group, an alkynyl group, or an aryl group, and particularly preferably an alkyl or an aryl group.

The alkyl group, alkenyl group, alkynyl group, aryl group or heterocyclic group represented by R₇ may further include a substituent. Examples of the substituent include the substituents of the above-mentioned alkyl group represented by R₂ and R₃ in the General Formula (1).

Some or all hydrogen atoms in the group represented by R₇ (preferably, some or all hydrogen atoms bonded to carbon atoms) are substituted with fluorine atoms. In this case, it is preferable that the above R₁ group is contained in R₇. The compound represented by the General Formula (2) contains fluorine atoms in an amount of satisfying the above-mentioned fluorine content rate.

Moreover, a hydroxyl group or a group represented by —COO— may be contained in the group represented by R₇.

Specific examples of the compound represented by the General Formula (2) are shown below. However, the present invention is not limited thereto.

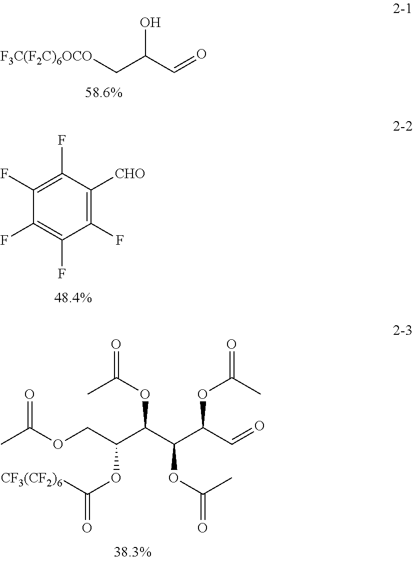

(Compound Represented by General Formula (3))

Next, a compound represented by General Formula (3) will be described.

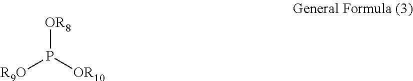

In the General Formula (3), each of the groups represented by R₈, R₉ and R₁₀ independently represents an alkyl group, an alkenyl group, an alkynyl group, an aryl group, a heterocyclic group, or a group composed of any combination of these. Preferred examples of the alkyl group, alkenyl group, alkynyl group, aryl group, and heterocyclic group include the examples of the above-mentioned R₂ and R₃ in the General Formula (1).

Each of the groups represented by R₈, R₉, and R₁₀ may further include a substituent. Examples of the substituent include the substituents of the above-mentioned alkyl group represented by R₂ and R₃ in the General Formula (1).

Some or all hydrogen atoms of at least one group of R₈ to R₁₀ (preferably, some or all hydrogen atoms bonded to carbon atoms) are substituted with fluorine atoms. Especially, it is preferable that the above R_{f} group is contained in at least one group of R₈ to R₁₀. The compound represented by the General Formula (3) contains fluorine atoms in an amount of satisfying the above-mentioned fluorine content rate.

Specific examples of the compound represented by the General Formula (3) are shown below. However, the present invention is not limited thereto.

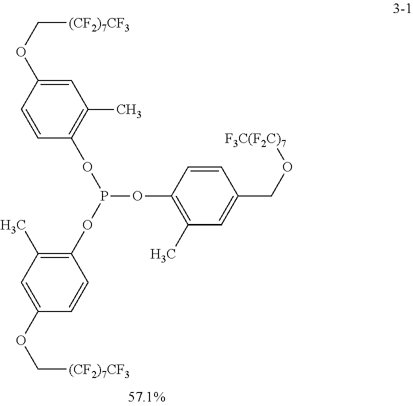

(Compound Represented by General Formula (4))

Next, a compound represented by General Formula (4) will be described.

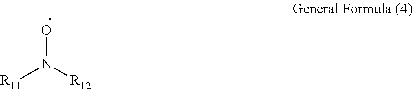

In the General Formula (4), each of R₁₁ and R₁₂ independently represents an alkyl group, an alkenyl group, an alkynyl group, an aryl group, a heterocyclic group, or a group composed of any combination of these. Preferred examples of the alkyl group, alkenyl group, alkynyl group, aryl group, and heterocyclic group include the examples of the above-mentioned R₂ and R₃ in the General Formula (1).

Each of the groups represented by R₁₁ and R₁₂ may further include a substituent. Examples of the substituent may include the substituents of the above-mentioned alkyl group represented by R₂ and R₃ in the General Formula (1).

Some or all hydrogen atoms of at least one group of R₁₁ to R₁₂ (preferably, some or all hydrogen atoms bonded to carbon atoms) are substituted with fluorine atoms. Especially, it is preferable that the above R_{f} group is contained in at least one group of R₁₁ to R₁₂. The compound represented by the General Formula (4) contains fluorine atoms in an amount of satisfying the above-mentioned fluorine content rate.

Specific examples of the compound represented by the General Formula (4) are shown below. However, the present invention is not limited thereto.

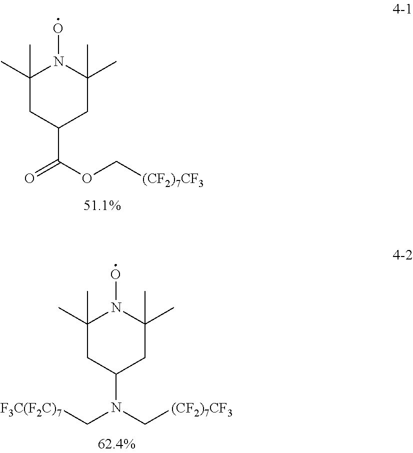

(Compound Represented by General Formula (5))

Next, a compound represented by General Formula (5) will be described.

Z—SH General Formula (5)

In the General Formula (5), Z represents an alkyl group, an alkenyl group, an alkynyl group, an aryl group, a heterocyclic group, or a group composed of any combination of these. Preferred examples of the alkyl group, alkenyl group, alkynyl group, aryl group, and heterocyclic group include the examples of the above-mentioned R₂ and R₃ in the General Formula (1).

The group represented by Z may further include a substituent. Examples of the substituent include the substituents of the above-mentioned alkyl group represented by R₂ and R₃ in the General Formula (1).

Some or all hydrogen atoms of the group represented by Z (preferably, some or all hydrogen atoms bonded to carbon atoms) are substituted with fluorine atoms. Especially, it is preferable that the above R_{f} group is contained in Z. The compound represented by the General Formula (5) contains fluorine atoms in an amount of satisfying the above-mentioned fluorine content rate.

The compound represented by General Formula (5) is preferably the respective compounds represented by General Formulae (51) to (54).

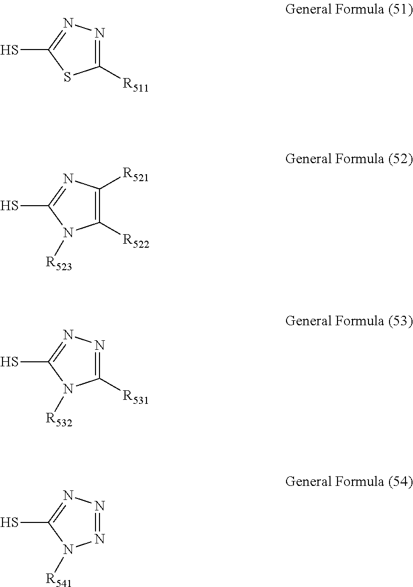

In the General Formula (51), R₅₁₁ represents a substituent containing a fluorine atom.

As the substituent, there can be exemplified the substituents of the above-mentioned alkyl group represented by R₂ and R₃ in the General Formula (1). The group represented by R₅₁₁ may further include a substituent. Examples of the substituent include the substituents of the above-mentioned alkyl group represented by R₂ and R₃ in the General Formula (1).

In addition, R₅₁₁ contains a fluorine atom. Especially, some or all hydrogen atoms of R₅₁₁ (preferably, some or all hydrogen atoms bonded to carbon atoms) are substituted with fluorine atoms. Further, it is preferable that the above R_{f} group is contained in R₅₁₁.

Specific examples of the compound represented by the General Formula (51) are shown below. However, the present invention is not limited thereto.

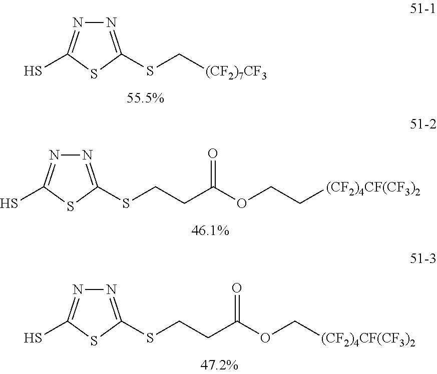

In the General Formula (52), each of R₅₂₁ and R₅₂₂ independently represents a hydrogen atom or a substituent. R₅₂₃ represents a hydrogen atom or a group which can be substituted with a nitrogen atom. Preferable examples of the group which can be substituted with a nitrogen atom include the groups exemplified in the above-mentioned R₂ and R₃ of the General Formula (1). Further, as the substituent, there can be exemplified the substituents of the above-mentioned alkyl group represented by R₂ and R₃ in the General Formula (1). R₅₂₁, R₅₂₂, and R₅₂₃ may be the same as or different from each other, and may be bonded to each other to form a ring.

At least one group of R₅₂₁, R₅₂₂, and R₅₂₃ contains a fluorine atom. Especially, it is preferable that some or all hydrogen atoms of at least one group of R₅₂₁, R₅₂₂, and R₅₂₃ (preferably, some or all hydrogen atoms bonded to carbon atoms) are substituted with fluorine atoms. In addition, it is more preferable that the above R_{f} group is contained in at least one group of R₅₂₁, R₅₂₂, and R₅₂₃.

Specific examples of the compound represented by the General Formula (52) are shown below. However, the present invention is not limited thereto.

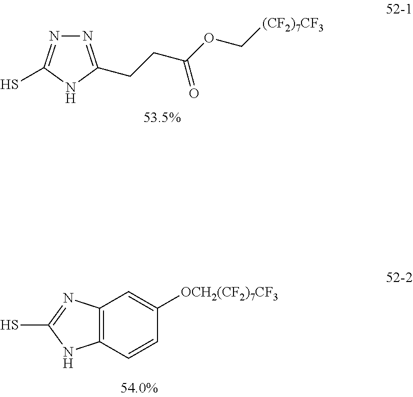

In the General Formula (53), R₅₃₁ represents a hydrogen atom or a substituent. R₅₃₂ represents a hydrogen atom or a group which can be substituted with a nitrogen atom. Preferable examples of the group which can be substituted with a nitrogen atom include the groups exemplified in the above-mentioned R₂ and R₃ of the General Formula (1). Further, as the substituent, there can be exemplified the substituents of the above-mentioned alkyl group represented by R₂ and R₃ in the General Formula (1). R₅₃₁ and R₅₃₂ may be the same as or different from each other, and may be bonded to each other to form a ring.

At least one group of R₅₃₁ and R₅₃₂ contains a fluorine atom. Especially, it is preferable that some or all hydrogen atoms of at least one group of R₅₃₁ and R₅₃₂ (preferably, some or all hydrogen atoms bonded to carbon atoms) are substituted with fluorine atoms. In addition, it is more preferable that the above R_{f} group is contained in at least one group of R₅₃₁ and R₅₃₂.

Specific examples of the compound represented by the General Formula (53) are shown below. However, the present invention is not limited thereto.

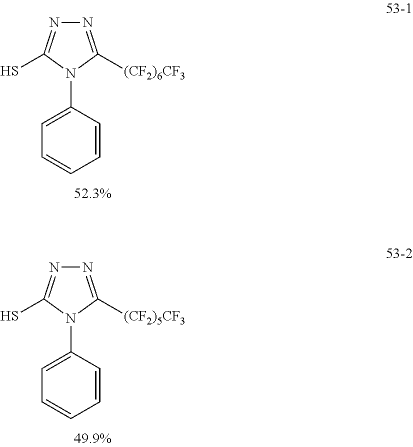

In the General Formula (54), R₅₄₁ represents a fluorine-atom containing group which can be substituted with a nitrogen atom. Preferable examples of the group which can be substituted with a nitrogen atom include the groups exemplified in the above-mentioned R₂ and R₃ of the General Formula (1).

R₅₄₁ contains a fluorine atom. Especially, it is preferable that some or all hydrogen atoms of R₅₄₁ (preferably, some or all hydrogen atoms bonded to carbon atoms) are substituted with fluorine atoms. In addition, it is more preferable that the above R_{f} group is contained in R₅₄₁.

Specific examples of the compound represented by the General Formula (54) are shown below. However, the present invention is not limited thereto.

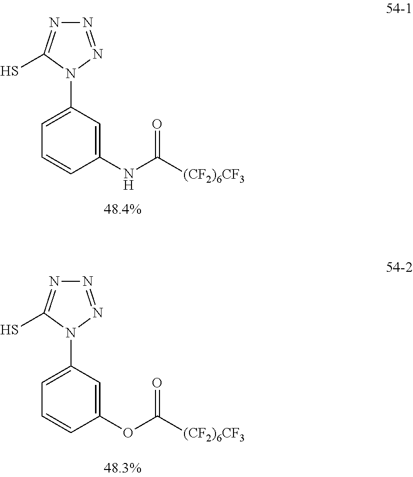

Meanwhile, as the most preferred embodiment of the compound represented by the General Formula (5), there is exemplified a compound represented by the following General Formula (Y).

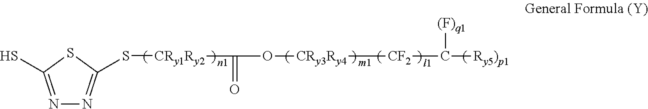

In the General Formula (Y), each of R_{y1} and R_{y2} independently represents a hydrogen atom or an alkyl group. n1 is 1 or 2, and preferably 2. When n1 is 2, a plurality of unit structures represented by CR_{y1}R_{y2} may be the same as or different from each other.

When each of R_{y1} and R_{y2} represents an alkyl group, the alkyl group preferably has 1 to 30 carbon atoms, more preferably 1 to 15 carbon atoms, and particularly preferably 1 to 6 carbon atoms. Preferable examples thereof include methyl, ethyl, n-propyl, isopropyl, t-butyl, n-octyl, eicosyl, chloromethyl, hydroxymethyl, aminoethyl, N,N-dimethylaminomethyl, 2-chloroethyl, 2-cyanoethyl, 2-hydroxyethyl, 2-(N,N-dimethylamino)ethyl, 2-ethylhexyl, and the like.

The structure represented by (CR_{y1}R_{y2})ₙ₁ is preferably —CH₂—, —CH₂CH₂— or —CH₂CH(CH₃)—, more preferably —CH₂CH₂— or —CH₂CH(CH₃)—, and particularly preferably —CH₂CH₂—.

Each of R_{y3} and R_{y4} independently represents a hydrogen atom or a substituent. m1 is an integer of 1 to 6. When m1 is 2 or more, a plurality of unit structures represented by CR_{y3}R_{y4} may be the same as or different from each other. Further, R_{y3} and R_{y4} may be bonded to each other to form a ring. The definition of the substituent is as described above.

The structure represented by (CR_{y3}R_{y4})ₘ₁ is preferably —CH₂—, —CH₂CH₂—, —CH₂CH(CH₃)—, —CH₂CH₂CH₂—, —CH₂CH(OH)CH₂— or —CH₂CH(CH₂OH)—, more preferably —CH₂—, —CH₂CH₂—, —CH₂CH(OH)CH₂— or —CH₂CH₂CH₂—, and particularly preferably —CH₂— or —CH₂CH₂—.

l1 is an integer of 1 to 6. Especially, in terms of the compatibility with the fluorine-based resin being excellent, l1 is preferably 2 to 5, and more preferably 3 to 4.

q1 represents 0 or 1, p1 represents 2 or 3, and p1+q1 represents 3. Especially, in terms of the compatibility with the fluorine-based resin being excellent, it is preferable that q1 is 1, and p1 is 2.

R_{y5} represents a perfluoroalkyl group having 1 to 14 carbon atoms. The perfluoroalkyl group may be either linear or branched.

Examples of the linear or branched perfluoroalkyl group having 1 to 14 carbon atoms include CF₃—, C₂F₅—, C₃F₇—, C₄F₉—, C₅F₁₁—, C₆F₁₃—, C₇F₁₅—, C₈F₁₇—, C₉F₁₉—, C₁₀F₂₁—, C₁₂F₂₅—, C₁₄F₂₉—, and the like.

(Compound Represented by General Formula (22))

Next, a compound represented by General Formula (22) will be described. Here, the compound represented by formula (22) contains fluorine atoms in an amount of satisfying the above-mentioned fluorine content rate.

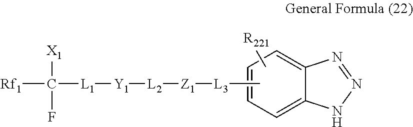

In the General Formula (22), Rf₁ represents a fluoroalkyl group having 22 or less carbon atoms, which may have an ethereal oxygen atom and in which at least one of hydrogen atoms is substituted with a fluorine atom, or represents a fluorine atom.

Hydrogen atoms in the fluoroalkyl group may be substituted with a halogen atom other than the fluorine atom. It is preferable that the halogen atom other than the fluorine atom is a chlorine atom. The ethereal oxygen atom (—O—) may be present in the carbon-carbon bond ring of the fluoroalkyl group, or may be present at the terminal of the fluoroalkyl group. The structure of the fluoroalkyl group may be a linear structure, a branched structure, a cyclic structure or a partially cyclic structure, and among these, a linear structure is preferable.

Rf₁ is preferably a perfluoroalkyl group or a polyfluoroalkyl group containing one hydrogen atom, and particularly preferably a perfluoroalkyl group (however, including a perfluoroalkyl group having an ethereal oxygen atom).

As Rf₁, a perfluoroalkyl group having 4 to 6 carbon atoms, or a perfluoroalkyl group having 4 to 9 carbon atoms and containing an ethereal oxygen atom is preferable.

Specific examples of Rf₁ include —CF₃, —CF₂CF₃, —CF₂CHF₂, —(CF₂)₂CF₃, —(CF₂)₃CF₃, —(CF₂)₄CF₃, —(CF₂)₅CF₃, —(CF₂)₆CF₃, —(CF₂)₇CF₃, —(CF₂)₈CF₃, —(CF₂)₉CF₃, —(CF₂)₁₁CF₃, —(CF₂)₁₅ CF₃, —CF(CF₃)O(CF₂)₅CF₃, —CF₂O(CF₂CF₂O)ₚCF₃ (p is an integer of 1 to 8), —CF(CF₃)O(CF₂CF(CF₃)O)_{q}C₆F₁₃ (q is an integer of 1 to 4), and —CF(CF₃)O(CF₂CF(CF₃)O)ᵣC₃F₇ (r is an integer of 1 to 5).

Particularly preferably, Rf₁ is —(CF₂)CF₃ or —(CF₂)₅CF₃.

X₁ represents a hydrogen atom, a fluorine atom, or a trifluoromethyl group.

Among them, a fluorine atom or trifluoromethyl group is preferable.

L₁ represents a single bond or an alkylene group having 1 to 6 carbon atoms. Especially, an alkylene group having 1 to 2 carbon atoms is preferable.

L₂ represents a single bond or an alkylene group having 1 to 6 carbon atoms which may be substituted with a hydroxyl group or a fluorine atom. Especially, an alkylene group having 1 to 2 carbon atoms is preferable.

L₃ represents a single bond or an alkylene group having 1 to 6 carbon atoms. Especially, a single bond or an alkylene group having 1 or 2 carbon atoms is preferable.

Each of Y₁ and Z₁ independently represents a single bond, —CO₂—, —CO—, —OC(═O)O—, —SO₃—, —CONR₂₂₂—, —NHCOO—, —O—, —S—, —SO₂NR₂₂₂—, or —NR₂₂₂—. R₂₂₂ represents a hydrogen atom or an alkyl group having 1 to 5 carbon atoms.

Among them, —CO₂—, —O—, —S—, —SO₂NR₂₂₂—, or —CONR₂₂₂— is preferable.

R₂₂₁ represents a hydrogen atom, a linear or branched alkyl group having 1 to 8 carbon atoms, or Rf₁—CFX₁-L₁-Y₁-L₂-Z₁-L₃-.

However, when both Y₁ and Z₁ are other than a single bond, L₂ represents an alkylene group having 1 to 6 carbon atoms which may be substituted with a fluorine atom.

Specific examples of the compound represented by the General Formula (22) are shown below. However, the present invention is not limited thereto.

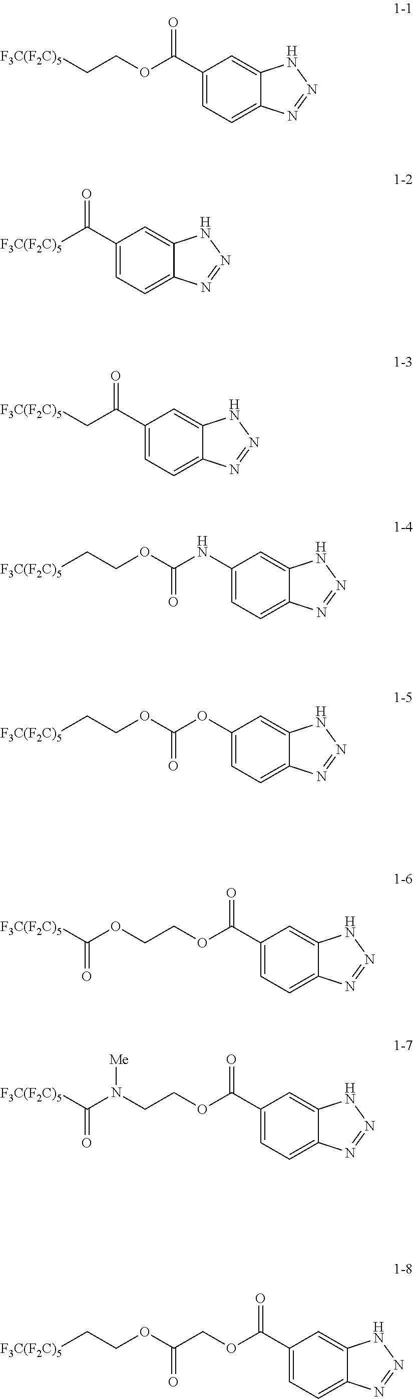

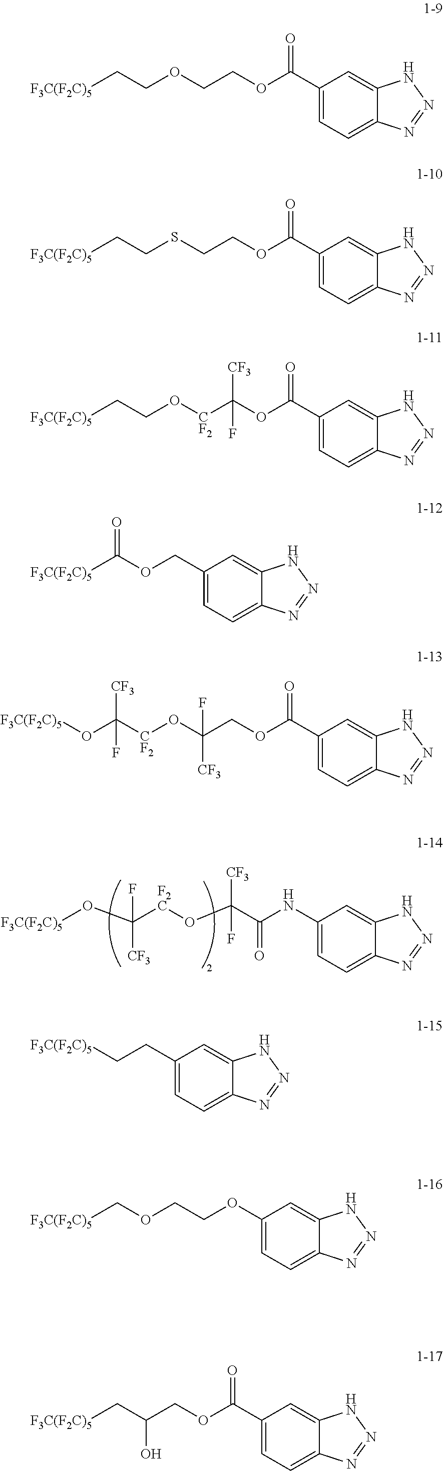

(Compound Represented by General Formula (23))

Next, a compound represented by General Formula (23) will be described. Here, the compound represented by General Formula (23) contains fluorine atoms in an amount of satisfying the above-mentioned fluorine content rate.

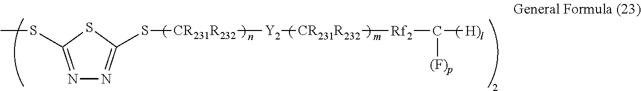

In the General Formula (23), each of R₂₃₁ and R₂₃₂ independently represents a hydrogen atom or an alkyl group. When each of R₂₃₁ and R₂₃₂ represents an alkyl group, the alkyl group has preferably 1 to 30 carbon atoms, more preferably 1 to 15 carbon atoms, and particularly preferably 1 to 6 carbon atoms. Preferable examples thereof include methyl, ethyl, n-propyl, isopropyl, t-butyl, n-octyl, eicosyl, chloromethyl, hydroxymethyl, aminoethyl, N,N-dimethylaminomethyl, 2-chloroethyl, 2-cyanoethyl, 2-hydroxyethyl, 2-(N,N-dimethylamino)ethyl, 2-ethylhexyl, and the like.

The structure represented by (CR₂₃₁R₂₃₂)ₙ is preferably —CH₂—, —CH₂CH₂— or —CH₂CH(CH₃)—, more preferably —CH₂CH₂— or —CH₂CH(CH₃)—, and particularly preferably —CH₂CH₂—.

Each of R₂₃₃ and R₂₃₄ independently represents a hydrogen atom or a substituent. Examples of the substituent may include the substituents of the above-mentioned alkyl group represented by R₂ and R₃.

The structure represented by (CR₂₃₃R₂₃₄)ₘ is preferably —CH₂—, —CH₂CH₂—, —CH₂CH(CH₃)—, —CH₂CH₂CH₂—, —CH₂CH(OH)CH₂— or —CH₂CH(CH₂OH)—, more preferably —CH₂—, —CH₂CH₂—, —CH₂CH(OH)CH₂— or —CH₂CH₂CH₂—, and particularly preferably —CH₂— or —CH₂CH₂—.

Y₂ represents a single bond, —CO—, or —COO—.

When Y₂ is a single bond or —CO—, n represents 0, and m represents an integer of 0 to 6. Especially, m is preferably 0 to 4, and more preferably 1 to 2.

When Y₂ is —COO—, n represents 1 or 2, and preferably 2. m represents an integer of 1 to 6, preferably 1 to 4, and more preferably 1 to 2.

Rf₂ represents a linear or branched perfluoroalkylene group having 1 to 20 carbon atoms, or a linear or branched perfluoroether group having 1 to 20 carbon atoms.

The number of carbon atoms in the perfluoroalkylene group is 1 to 20, but is preferably 2 to 15, and more preferably 3 to 12. Specific examples of the perfluoroalkylene group include —C₄F₈—, —C₅F₁₀—, —C₆F₁₂—, —C₇F₁₄—, —C₈F₁₆—, —C₉F₁₈—, —C₁₀F₂₀—, —C₁₂F₂₄—, and the like.

The perfluoroether group means a group in which an ethereal oxygen atom (—O—) is inserted between the carbon atoms at one or more places in the perfluoroalkylene group or is inserted in the bonding end of the perfluoroalkylene group. The number of carbon atoms in the perfluoroalkylene group is 1 to 20, but is preferably 2 to 15, and more preferably 3 to 12. As an specific example of the perfluoroether group, there is exemplified a perfluoroether group represented by the Formula —(C_{g}F_{2g}O)ₕ— (here, each of g is independently an integer of 1 to 20, h is an integer of 1 or more, and g×h≦20).

p represents an integer of 2 to 3, l represents an integer of 0 to 1, and p+l=3. Especially, it is preferable that p is 3 and l is 0.

Specific examples of the compound represented by the General Formula (23) are shown below. However, the present invention is not limited thereto.

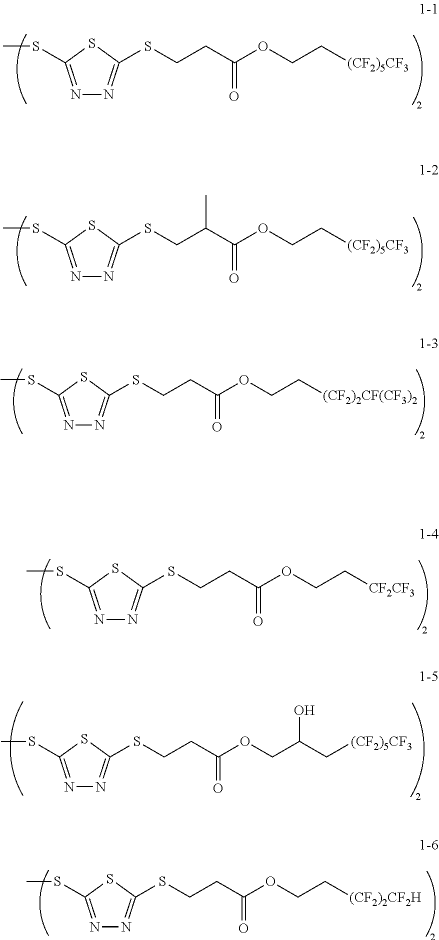

(Compound Having Group Represented by General Formula (24) and Group Represented by General Formula (25))

Next, a compound (hereinafter, referred to as “compound X”) having a group represented by General Formula (24) and a group represented by General Formula (25) will be described. Here, the compound X contains fluorine atoms in an amount of satisfying the above-mentioned fluorine content rate.

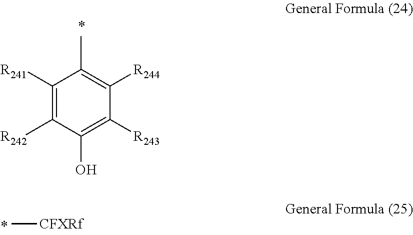

In the General Formula (24), each of R₂₄₁, R₂₄₂, R₂₄₃, and R₂₄₄ independently represents a hydrogen atom or a substituent. Examples of the substituent include the substituents of the above-mentioned alkyl group represented by R₂ and R₃. Especially, it is preferable for the substituent to be an alkyl group, and it is particularly preferable for each of R₂₄₂ and R₂₄₃ to be an alkyl group (particularly, tert-butyl group). Further, it is preferable for each of R₂₄₁ and R₂₄₄ to be a hydrogen atom.

* represents a binding position.

In the General Formula (25), X represents a hydrogen atom, a fluorine atom, or a trifluoromethyl group. Among them, a fluorine atom or a trifluoromethyl group is preferable.

Rf represents a fluoroalkyl group having 20 or loss carbon atoms, which may have an ethereal oxygen atom and in which at least one of hydrogen atoms is substituted with a fluorine atom, or represents a fluorine atom. The definition of Rf is the same as that of the above Rf₁, except that the number of carbon atoms is different, and the preferred embodiments of Rf is also the same as those of the above Rf₁.

* represents a binding position.

As a preferred embodiment of the compound X, there is exemplified a polymer having a repeating unit represented by the following General Formula (26) and a repeating unit represented by the following General Formula (27).

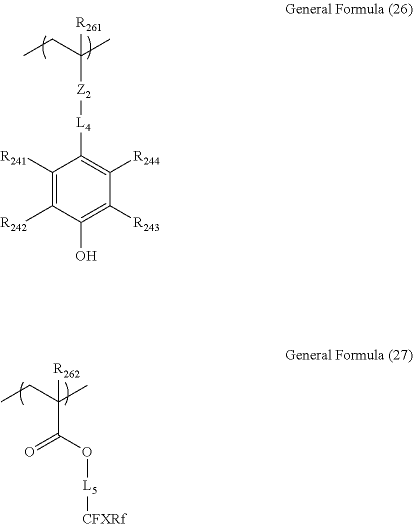

In the General Formula (26) and the General Formula (27), each of R₂₆₁ and R₂₆₂ independently represents a hydrogen atom or a substituted or unsubstituted alkyl group having 1 to 4 carbon atoms.

Z₂ represents a single bond, an ester group, an amide group, or an ether group.

L₄ represents a single bond or a divalent organic group. In a preferred embodiment, the organic group represented by L₄ is a linear, branched, or cyclic alkylene group, an aromatic group, or a group composed of the combination thereof. In the group composed of the combination of an alkylene group and an aromatic group, the alkylene group and the aromatic group may be combined through an ether group, an ester group, an amide group, a urethane group, or a urea group. Especially, it is preferable that the total number of carbon atoms in L₄ is 1 to 15. Here, the total number of carbon atoms means, for example, the total number of carbon atoms contained in a substituted or unsubstituted divalent organic group represented by L₄. Specific examples of the divalent organic group include a methylene group, an ethylene group, a propylene group, a butylene group, a phenylene group, substitutes of these with a methoxy group, a hydroxyl group, a chlorine atom, a bromine atom, a fluorine atom, or the like, and a group composed of any combination of these.

L₅ represents a single bond or a divalent organic group having 1 to 6 carbon atoms and containing no fluorine. Especially, an alkylene group having 2 to 4 carbon atoms is preferable.

The definitions of R₂₄₁ to R₂₄₄, X and Rf in the General Formula (26) and the General Formula (27) are as described above.

The content of the repeating unit represented by the General Formula (26) in the polymer is not particularly limited, but, in terms of the effect of the present invention being more excellent, the content is preferably 5 to 90 mol %, and more preferably 10 to 70 mol %, based on the whole repeating unit in the polymer.

The content of the repeating unit represented by the General Formula (27) in the polymer is not particularly limited, but, in terms of the effect of the present invention being more excellent, the content is preferably 10 to 95 mol %, and more preferably 30 to 90 mol %, based on the whole repeating unit in the polymer.

The weight average molecular weight of the polymer is not particularly limited, but, in terms of the ion migration inhibiting ability being more excellent, the weight average molecular weight is preferably 3,000 to 500,000, and more preferably 5,000 to 100,000.

Specific examples of the compound X are shown below. However, the present invention is not limited thereto.

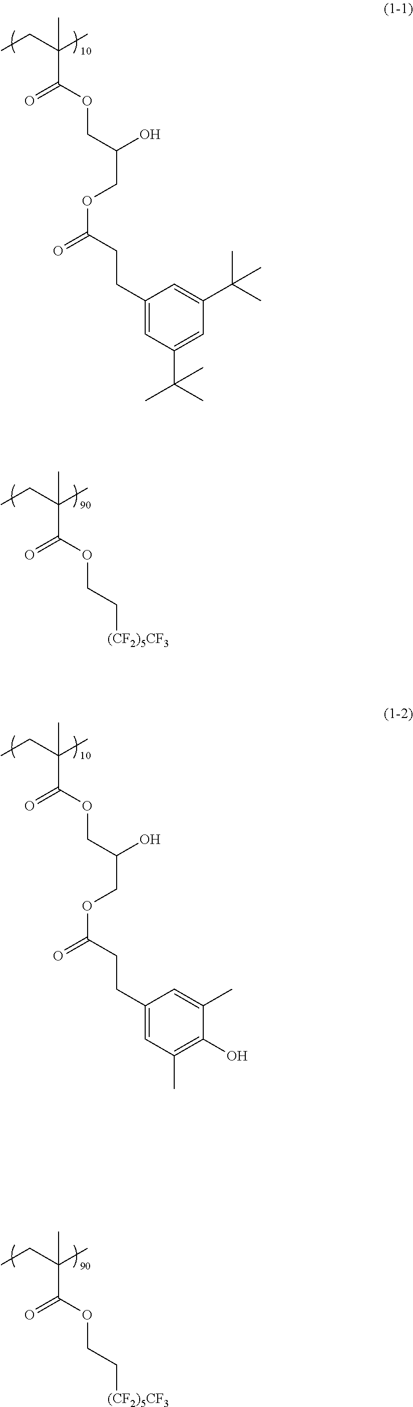

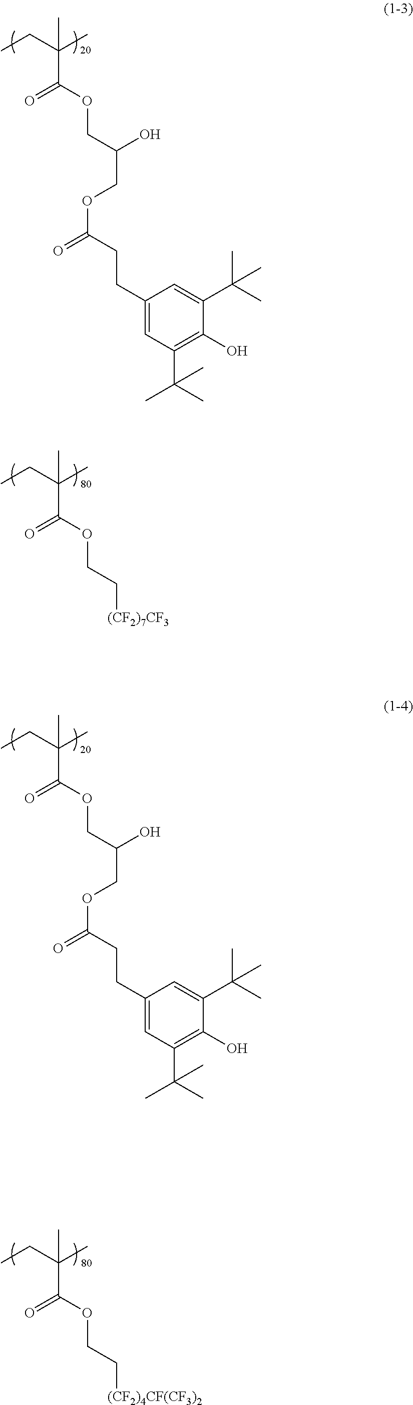

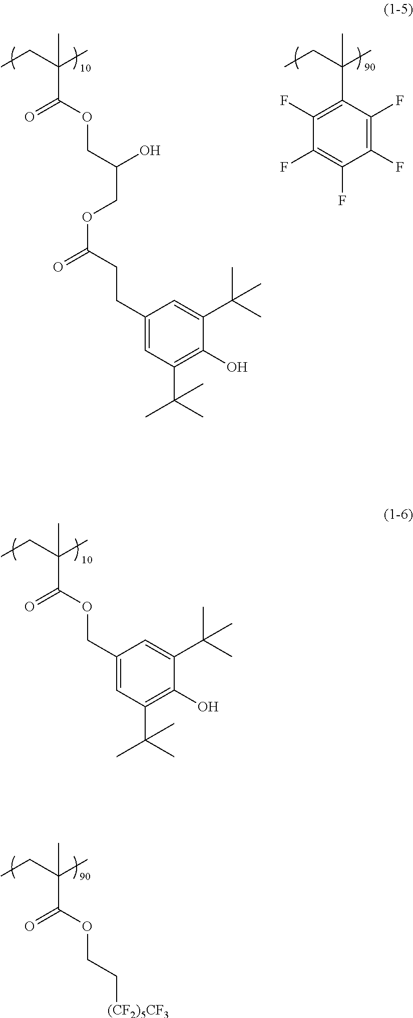

The migration inhibitor (B) is preferably a compound represented by any one of General Formula (6), General Formula (7), General Formula (10), General Formula (11), General Formula (21), General Formula (51), General Formula (53), and General Formula (54), more preferably a compound represented by any one of General Formula (10), General Formula (11), General Formula (51), General Formula (53), and General Formula (54), and particularly preferably a compound represented by any one of General Formula (10), General Formula (11), and General Formula (51).

Although the detailed mechanism of the effects exhibited by the migration inhibitor (B) in the present invention has not been sufficiently elucidated, the compound represented by General Formula (1) is an organic compound exhibiting reducibility, which is known as Kendal-Pelz law, or is a reducing organic compound, which is generally known as a developing agent of various photographic sensitive materials. For example, the general structural formula thereof is exemplified in page 299 of “The Theory of the Photographic Process”, 4^{th} edition, written by T. H. James, Macmillan Publishing Co., Inc.; lines 22 to 34, column 12 of U.S. Pat. No. 4,845,019 B; and the like, and the typical compound thereof is exemplified in pages 298 to 327 of “The Theory of the Photographic Process”, 4^{th} edition, written by T. H. James, Macmillan Publishing Co., Inc.; page 6 of JP 2788831 B; pages 1 to 4 of JP 2890055 B; pages 12 to 15 of JP 4727637 B; and the like. Further, the compounds represented by General Formula (2), General Formula (3) and General Formula (4) and the compound X are also compounds exhibiting reducibility. It is presumed that if each of these reducing compounds exists in the vicinity of metal wiring in a fixed amount or more, the reducing compound reacts with metal ions generated by the ion migration of the metal wiring to reduce the metal ions by the self-oxidation thereof, thereby suppressing the migration of the metal wiring.

The compounds represented by General Formula (5), General Formula (22) and General Formula (23) are known as compounds capable of being adsorbed on a metal or compounds capable of being coordinated with a metal ion. It is presumed that the compound is adsorbed on the surface of a metal or forms a complex with the metal to form a film on the surface of the metal, thereby exhibiting the effect of corrosion protection or rust prevention, or that the compound forms a complex with the generated metal ions to suppress the diffusion of the metal ions, thereby suppressing the migration of the metal wiring.

As another preferred embodiment of the aforementioned compound represented by General Formula (1), a compound represented by General Formula (60) below is exemplified. The compound represented by General Formula (60) is a compound including the compounds represented by General Formulae (6) to (13).

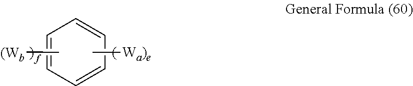

In General Formula (60), each of Wₐ independently represents OH, NR₂R₃ or CHR₄R₅. Each of W_{b} independently represents a hydrogen atom or a substituent. e represents 2, and f represents 4. Here, in the case in which at least one of Wₐ represents OH or NR₂R₃ and the one of Wₐ is NR₂R₃, the other Wₐ represents OH or NR₂R₃. Definitions of R₂ to R₅ are as described above.

At least one group of Wₐ and W_{b} includes a fluorine atom. Especially, it is preferable that some or all of hydrogen atoms of at least one group of Wₐ and W_{b} (preferably, a part or all of hydrogen atoms bonded to a carbon atom) are substituted with fluorine atoms. Further, it is more preferable that at least one group of Wₐ and W_{b} includes the aforementioned R_{f} group.

(Sealing Resin Composition)

The sealing resin composition contains the aforementioned fluorine-based resin (A) and migration inhibitor (B).

The mass ratio ((B)/(A)) of the migration inhibitor (B) to the fluorine-based resin (A) is equal to or more than 0.0010 and less than 0.10. Especially, from the viewpoints that the ion migration-inhibiting ability of the sealing layer (sealing film) formed from the sealing resin composition is more excellent and the planar characteristics thereof are also more excellent, the mass ratio ((B)/(A)) thereof is preferably 0.0025 to 0.06, and more preferably 0.010 to 0.05.

When the mass ratio ((B)/(A)) thereof is less than 0.0010, the ion migration-inhibiting ability is deteriorated. When the mass ratio ((B)/(A)) thereof is equal to or more than 0.10, the planar characteristics or the insulation performance is lowered.

If necessary, the sealing resin composition may contain a compound other than the aforementioned fluorine-based resin (A) and migration inhibitor (B).

For example, the sealing resin composition may contain a solvent. If the sealing resin composition contains a solvent, the handling property of the sealing resin composition is improved, and it is easy to form a sealing layer having a desired thickness.

The type of the solvent used is not particularly limited, and as the solvent, water or an organic solvent is exemplified.

Examples of the organic solvent used include alcohol-based solvents (for example, methanol, ethanol, isopropanol, sec-butanol, carbitol, and diethylene glycol monoethyl ether), ketone-based solvents (for example, acetone, methyl ethyl ketone, and cyclohexanone), aromatic hydrocarbon solvents (for example, toluene and xylene), amide-based solvents (for example, formamide, dimethyl acetamide, N-methyl pyrrolidone, and dimethyl propylene urea), nitrile-based solvents (for example, acetonitrile and propionitrile), ester-based solvents (for example, methyl acetate and ethyl acetate), carbonate-based solvents (for example, dimethyl carbonate and diethyl carbonate), ether-based solvents, halogen-based solvents, and the like. These solvents may be used in a mixture of two or more thereof.

As the use of the sealing resin composition, the sealing resin composition is used for coating silver wiring or a laminate including the silver wiring. More specifically, the sealing resin composition is used for coating the silver wiring by forming a sealing layer (sealing film) on the silver wiring. Further, the sealing resin composition is used for coating a laminate including the silver wiring by forming a sealing layer (sealing film) on the laminate. Here, the laminate including the silver wiring is not particularly limited as long as it includes the silver wiring. Generally, as the laminate, a laminate including a substrate, the silver wiring disposed on the substrate, and an insulating layer disposed on the silver wiring is used. The sealing resin composition is applied onto the insulating layer of the laminate to form a sealing layer (sealing film).

The method of using the sealing resin composition is not particularly limited, and generally, a method of forming a sealing layer (sealing film) by applying the sealing resin composition onto a substrate with silver wiring or a laminate including silver wiring is applied.

The method of applying the sealing resin composition is not particularly limited, and a known method (bar coating, spin coating, knife coating, or doctor blade coating) is applied.

If necessary, in order to remove a solvent, drying treatment may be performed after the application of the sealing resin composition. The heating conditions in the drying treatment are not particularly limited. However, from the viewpoint of productivity, the heating is preferably performed at 50° C. to 250° C. (preferably, 80° C. to 180° C.) for 5 minutes to 2 hours (preferably, 10 minutes to 1 hour).

<Sealing Film>

Next, the sealing film of the present invention will be described in detail.

The sealing film contains the aforementioned fluorine-based resin (A) and the aforementioned migration inhibitor (B). The mass ratio ((B)/(A)) of the migration inhibitor (B) to the fluorine-based resin (A) in the sealing film is the same as that in the sealing resin composition, and preferred embodiments of the mass ratio ((B)/(A)) in the sealing film are also the same as those in the sealing resin composition. The sealing film is used for coating silver wiring or a laminate including the silver wiring.

The sealing film may be a sealing film not having a substrate (substrate-less sealing film), or may be a sealing film having a substrate in which a sealing film is disposed on at least one principal surface of the substrate (sealing film with a substrate, for example, a double-sided sealing film having a sealing film on each side of the substrate and a single-sided sealing film having a sealing film only on one side of the substrate).

In the sealing film with a substrate, the type of the substrate used is not particularly limited, but a transparent substrate is preferably used. Examples of the transparent substrate include a polyethylene terephthalate film, a polybutylene terephthalate film, a polyethylene naphthalate film, a polyethylene film, a polypropylene film, a cellophane film, a diacetylcellulose film, a triacetylcellulose film, an acetylcellulose butyrate film, a polyvinyl chloride film, a polyvinylidene chloride film, a polyvinyl alcohol film, an ethylene-vinyl acetate copolymer film, a polystyrene film, a polycarbonate film, a polymethyl pentene film, a polysulfone film, a polyether ether ketone film, a polyether sulfone film, a polyether imide film, a polyimide film, a fluorine resin film, a nylon film, an acrylic resin film, and the like.

The thickness of the sealing film is not particularly limited, and in terms of application to electronic precision devices, the thickness thereof is preferably 0.3 μm to 30 μm, and more preferably 0.5 μm to 20 μm.

The sealing film can be manufactured by a known method. For example, in the case of the substrate-less sealing film, the sealing film can be manufactured by applying the aforementioned sealing resin composition onto a separator (release liner) such that the thickness thereof after drying becomes a predetermined thickness to provide a coating layer of the sealing resin composition, then drying the coating layer and, if necessary, curing the coating layer, and thereafter detaching the separator from the coating layer.

In the case of the sealing film with a substrate, the sealing film may be manufactured by directly applying the sealing resin composition onto the surface of a substrate and drying the applied composition (direct coating method), or may be manufactured by forming a coating layer of the sealing resin composition on a separator in the same manner as above and then transferring (sticking) the coating layer to a substrate (transfer method).

From the viewpoint that the ion migration between the metal wiring can be further suppressed, the sealing film of the present invention can be widely applied to, for example, touch panels, electrodes for displays, electromagnetic wave shields, electrodes for organic or inorganic EL displays, electronic papers, electrodes for flexible displays, integrated solar cells, display devices (OLED devices and LED devices), and other various devices (TFT devices).

<Wiring Board>

Next, a preferred embodiment of the wiring board of the present invention will be described in detail with reference to the accompanying drawing.

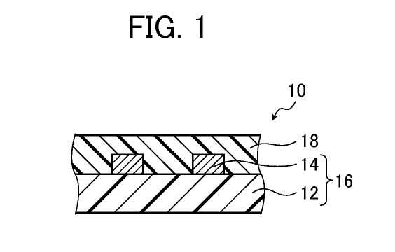

FIG. 1 is a schematic cross-sectional view showing a preferred embodiment of the wiring board of the present invention. In FIG. 1, the wiring board 10 includes a substrate 12, silver wiring 14 disposed on the substrate 12, and a sealing film 18 covering the silver wiring 14. Here, the substrate 12 and the silver wiring 14 constitute the substrate with silver wiring 16.

Hereinafter, each member (substrate 12, silver wiring 14, and sealing film 18) will be described in detail.

(Substrate)

The type of the substrate is not particularly limited as long as the substrate can support the silver wiring, but it is preferable for the substrate to be an insulating substrate having insulation properties. For example, an organic substrate, a ceramic substrate, a glass substrate, or the like can be used as the insulating substrate.

In addition, the substrate may have a laminated structure composed of at least two substrates selected from the group consisting of an organic substrate, a ceramic substrate, and a glass substrate.

As the raw material of the organic substrate, resins are exemplified. For example, a thermosetting resin, a thermoplastic resin, or a mixture thereof is preferably used. Examples of the thermosetting resin include a phenolic resin, a urea resin, a melamine resin, an alkyd resin, an acrylic resin, an unsaturated polyester resin, a diallyl phthalate resin, an epoxy resin, a silicone resin, a furan resin, a ketone resin, a xylene resin, a benzocyclobutene resin, and the like. Examples of the thermoplastic resin include a polyimide resin, a polyphenylene oxide resin, a polyphenylene sulfide resin, an aramid resin, a liquid crystal polymer, and the like.

In addition, as the raw material of the organic substrate, a glass woven fabric, a glass non-woven fabric, an aramid woven fabric, an aramid non-woven fabric, an aromatic polyamide woven fabric, a material in which each of these fabrics is impregnated with each of the above-mentioned resins, or the like can also be used.

(Silver Wiring)

The silver wiring mainly contains silver. The silver may be contained in the silver wiring in the form of a silver alloy. When the silver wiring contains a silver alloy, examples of metal contained in the silver wiring together with the silver include tin, palladium, gold, nickel, chromium, and the like. A resin component such as a binder or a photosensitive compound may be contained in the silver wiring to the extent not impairing the effects of the present invention. Further, if necessary, other components may be contained in the silver wiring.

The width of the silver wiring is not particularly limited. However, from the viewpoint of securing the electrical reliability in the highly-integrated portion and the drawing wiring portion (leading out wiring portion) of the wiring board, the width thereof is preferably 0.1 μm to 10000 μm, more preferably 0.1 μm to 300 μm, even more preferably 0.1 μm to 100 μm, and particularly preferably 0.2 μm to 50 μm.

The interval between the silver wiring is not particularly limited. However, from the viewpoint of high integration of the wiring board, it is preferably 0.1 μm to 1000 μm, more preferably 0.1 μm to 300 μm, even more preferably 0.1 μm to 100 μm, and particularly preferably 0.2 μm to 50 μm.

The shape of the silver wiring is not particularly limited, and may be any shape. Examples of the shape of the wiring board include a linear shape, a curved shape, a rectangular shape, a circular shape, and the like. The arrangement (pattern) of the silver wiring is not particularly limited and, for example, a stripe pattern is exemplified.

Further, although in the wiring board shown in FIG. 1, the number of the silver wiring 14 is two, the number thereof is not particularly limited. Generally, a plurality of pieces of silver wiring is provided.

The thickness of the silver wiring is not particularly limited. However, from the viewpoint of high integration of the wiring board, the thickness thereof is preferably 0.001 μm to 100 μm, more preferably 0.01 μm to 30 μm, and even more preferably 0.01 μm to 20 μm.

The method of forming the silver wiring is not particularly limited, and examples thereof include a physical film forming method such as a deposition method and a sputtering method, a chemical vapor phase method such as a CVD method, a method of applying a silver paste containing silver nonoparticles or silver nanowires, a method of using a silver salt disclosed in JP 2009-188360 A, and the like.

In FIG. 1, the silver wiring 14 is provided only on one side of the substrate 12, but may be provided on both sides thereof. That is, the substrate with silver wiring 16 may be a single-sided substrate, or may be a double-sided substrate. When the silver wiring 14 is provided on both sides of the substrate 12, the sealing film 18 may also be provided on both sides thereof.

Further, in FIG. 1, an example of a wiring structure, in which the silver wiring 14 is a single layer, is shown. However, needless to say, the wiring structure is not limited thereto. For example, by using a substrate with silver wiring in which a plurality of pieces of silver wiring and a plurality of substrates are alternately laminated (multi-layer wiring board), a wiring board having a multi-layer wiring structure may be constituted.

(Sealing Film)

The sealing film is a layer which is disposed on the surface of the silver wiring side of the substrate with silver wiring, covers the surface of the silver wiring, and suppresses the ion migration of silver between the silver wiring. In other words, the sealing film corresponds to a silver ion diffusion inhibiting layer.

Definition of the sealing film is as described above.

The method of manufacturing the sealing film is not particularly limited. For example, there can be exemplified a method of forming a sealing film by applying the aforementioned sealing resin composition onto a substrate with silver wiring and, if necessary, removing a solvent. In addition, there can be exemplified a method of directly laminating (sticking) a sealing film onto a substrate with silver wiring.

From the viewpoint that the ion migration between the metal wiring can be further suppressed, the wiring board of the present invention can be widely applied to, for example, touch panels, electrodes for displays, electromagnetic wave shields, electrodes for organic or inorganic EL displays, electronic papers, electrodes for flexible displays, integrated solar cells, display devices (OLED devices, and LED devices), and other various devices (TFT devices).

### EXAMPLES

Hereinafter, the present invention will be described in more detail by Examples, but the present invention is not limited thereto.

### Synthesis Example 1

### Compound A-1

3-(3,5-di-tert-butyl-4-hydroxyphenyl)propionic acid (3.5 g, 12.6 mmol), dichloromethane (20 ml), 2,2,3,3,4,4,5,5,6,6,7,7,8,8,9,9,10,10,10-nonadecafluorodecane-1-ol (6.3 g, 12.6 mmol), tetrahydrofuran (10 ml), 1-ethyl-3-(3-dimethylaminopropyl) carbodiimide hydrochloride (2.4 g, 12.6 mmol), and 4-dimethylaminopyridine (0.05 g, 0.4 mmol) were put into a reaction container in this order to obtain a reaction solution.

The reaction solution was stirred at room temperature for 3 hours, 1N hydrochloric acid (50 ml) was added thereto, and then the resultant was extracted with 100 ml of ethyl acetate to obtain an organic layer. The organic layer was washed with saturated saline and dried with magnesium sulfate. After solid content was separated by filtration, the organic layer was concentrated under reduced pressure to obtain white crude crystals. The white crude crystals were recrystallized with methanol to obtain 6.0 g of the compound A-1 (yield 63%).

¹H-NMR spectrum of the obtained compound A-1 was as follows.

¹H-NMR (solvent: deuterated chloroform, reference: tetramethylsilane)

6.98 (2H, s), 5.09 (1H, s), 4.59 (2H, t), 2.90 (2H, t), 2.71 (2H, t), 1.43 (9H, s)

In the ¹H-NMR data, the peak of each proton was observed at the characteristic position, and thus the resulting product was identified as the compound A-1.

Here, the fluorine content rate of the compound A-1 was 47.5 mass %.

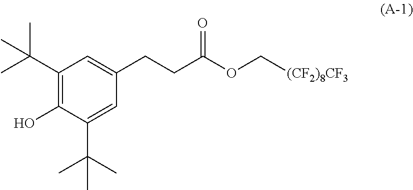

### Synthesis Example 2

### Compound A-2

1,3,4-thiadiazole-2,5-dithiol (manufactured by Wako Pure Chemical Industries, Ltd.) (4.0 g, 26.6 mmol) and tetrahydrofuran (80 ml) were put into a reaction container, and completely dissolved to obtain a reaction solution. Then, 3,3,4,4,5,5,6,6,7,8,8,8-dodecafluoro-7-(trifluoromethyl)octyl acrylate (12.5 g, 26.6 mmol) was dropped into the reaction solution over 0.5 hours by a dropping funnel. The reaction solution was stirred at 65° C. for 6 hours, cooled to room temperature, and then concentrated under reduced pressure. To the reaction solution, 200 mL of hexane was added, and the resultant was cooled in an ice bath to obtain 16 g of crude crystals. 8 g of the crude crystals were purified by silica gel column chromatography (mobile phase: hexane/ethyl acetate=2/1 to 1/1) to obtain 6 g of the compound A-2 (yield 72%).

¹H-NMR spectrum of the obtained compound A-2 was as follows.

¹H-NMR (solvent: deuterated chloroform, reference: tetramethylsilane)

11.1 (1H, br), 4.44 (2H, t), 3.40 (2H, t), 2.85 (2H, t), 2.49 (2H, t), 2.49 (2H, m)

In the ¹H-NMR data, the peak of each proton was observed at the characteristic position, and thus the resulting product was identified as the compound A-2.

Here, the fluorine content rate of the compound A-2 was 47.2 mass %.

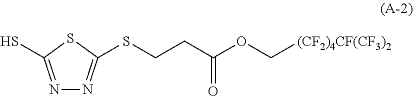

### Synthesis Example 3

### Compound A-3

The compound A-3 was synthesized according to the same procedure as in Synthesis Example 1, except that 2,2,2-trifluoroethanol was used instead of 2,2,3,3,4,4,5,5,6,6,7,7,8,8,9,9,10,10,10,10-nonadecafluorodecane-1-ol.

Here, the fluorine content rate of the compound A-3 was 15.8 mass %.

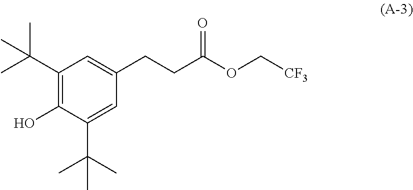 [SMILES: CC(C)(C)c1cc(CCC(=O)OCC(F)(F)F)cc(C(C)(C)C)c1O]

### Synthesis Example 4

### Compound A-4

The compound A-4 was synthesized according to Synthesis Example of the compound 3c disclosed in the Journal of Organic Chemistry, 2005, vol. 70, 1328-1339.

Here, the fluorine content rate of the compound A-4 is 0 mass %.

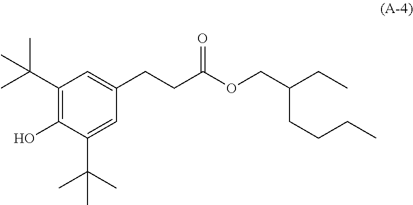 [SMILES: CCCCC(CC)COC(=O)CCc1cc(C(C)(C)C)c(O)c(C(C)(C)C)c1]

### Synthesis Example 5

### Compound A-5

1H-benzotriazole-5-carboxylic acid (1.5 g, 9.19 mmol), tetrahydrofuran (27 ml), dimethylformamide (3 ml), 3,3,4,4,5,5,6,6,7,7,8,8,8-tridecafluoro-1-octanol (3.35 g, 9.19 mmol), 1-ethyl-3-(3-dimethylaminopropyl)carbodiimide hydrochloride (1.76 g, 9.19 mmol), and 4-dimethylaminopyridine (0.11 g, 0.91 mmol) were put into a reaction container in this order to obtain a reaction solution. After the reaction solution was stirred at 70° C. for 24 hours, 50 ml of water was added thereto, and then the reaction solution was extracted with 100 ml of ethyl acetate to obtain an organic layer. The organic layer was washed with saturated saline and dried with magnesium sulfate to obtain solids. After solid content was separated by filtration, the organic layer was concentrated under reduced pressure. The resultant was purified by silica gel column chromatography (mobile phase: hexane/ethyl acetate=2/1) to obtain 3.1 g of the compound A-5 (yield 66%).

Here, the fluorine content rate of the compound A-5 was 48.5 mass %.

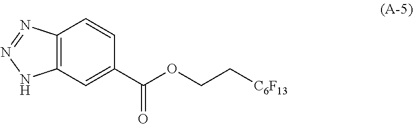

### Synthesis Example 6

### Compound A-6

Compound A-6A was synthesized according to the following scheme.

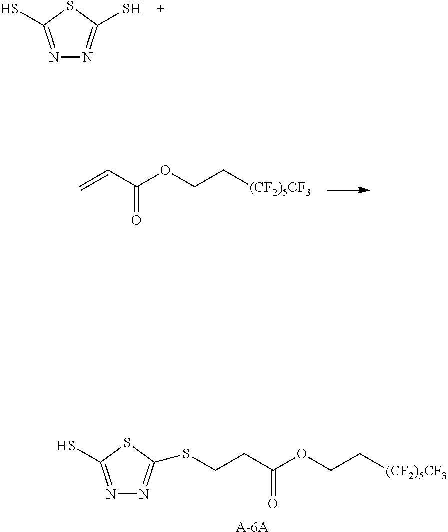

1,3,4-thiadiazole-2,5-dithiol (manufactured by Wako Pure Chemical Industries, Ltd.) (4.0 g, 26.6 mmol) and tetrahydrofuran (80 ml) were put into a reaction container, and completely dissolved to obtain a reaction solution. Then, 3,3,4,4,5,5,6,6,7,7,8,8,8-tridecafluorooctyl acrylate (11.3 g, 26.6 mmol) was dropped into the reaction solution over 0.5 hours by a dropping funnel. The reaction solution was stirred at 65° C. for 6 hours, cooled to room temperature, and then concentrated under reduced pressure. To the resulting reaction mixture, 200 mL of hexane was added, and the resultant was cooled in an ice bath to obtain 15 g of crude crystals. 7.5 g of the crude crystals were purified by silica gel column chromatography (mobile phase: hexane/ethyl acetate=2/1 to 1/1) to obtain 6 g of the compound A-6A (yield 79%).

Next, compound A-6 was synthesized using the obtained compound A-6A according to the following scheme.

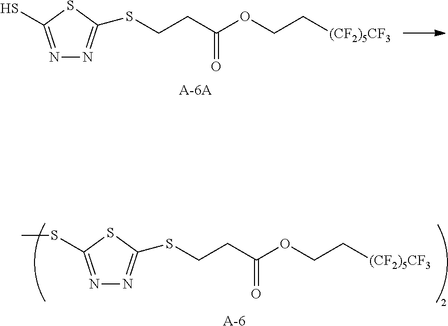

The compound A-6A (3.0 g, 5.28 mmol) and ethyl acetate (20 ml) were put into a reaction container, and completely dissolved to obtain a reaction solution. To the reaction solution, sodium iodide (79.1 mg, 0.528 mmol) and 30% hydrogen peroxide (22.11 mmol, 2.39 g) were added in this order, and the reaction solution was stirred at room temperature for 1 hour to precipitate crystals. The crystals precipitated were washed with 100 ml of water to obtain crude crystals, and 2.7 g of the crude crystals were purified by silica gel column chromatography (mobile phase: hexane/ethyl acetate=2/1 to 1/1) to obtain 2.4 g of the compound A-6 (yield 80%).

¹H-NMR spectrum of the obtained compound A-6 was as follows.

¹H-NMR (solvent: deuterated chloroform, reference: tetramethylsilane): 4.43 (2H, t), 3.60 (2H, t), 2.95 (2H, t), 2.49 (2H, m)

In the ¹H-NMR data, the peak of each proton was observed at the characteristic position, and thus the resulting product was identified as the compound A-6.

Here, the fluorine content rate of the compound A-6 was 43.5 mass %.

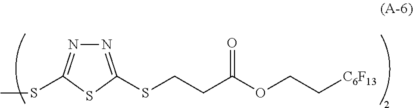

### Synthesis Example 7

### Compound A-7

27.3 g of 4-methyl-2-pentanone (manufactured by Wako Pure Chemical Industries, Ltd.) was put into a 300 ml three-neck flask, and heated to 80° C. under a nitrogen stream. Then, a solution of 37.6 g of 3,3,4,4,5,5,6,6,7,7,8,8,8-tridecafluorooctyl acrylate, 1.42 g of glycidyl methacrylate (manufactured by Tokyo Chemical Industry Co., Ltd.), 0.92 g of V-601 (manufactured by Wako Pure Chemical Industries, Ltd.), and 63.8 g of 4-methyl-2-pentanone (manufactured by Wako Pure Chemical Industries, Ltd.) was dropped thereinto over 4 hours. After the completion of the dropping, the resultant was stirred for 2 hours, heated to 90° C., and further stirred for 2 hours. To the resulting reaction solution, 3.34 g of 3-(3,5-di-tert-butyl-4-hydroxyphenyl)propionic acid and 0.21 g of dimethyldodecylamine (manufactured by Wako Pure Chemical Industries, Ltd.) were added, and the reaction solution was heated to 120° C. and reacted for 24 hours. After the completion of the reaction, to the resultant, 500 ml of hexane and 500 ml of ethyl acetate were added to obtain an organic layer. The organic layer was washed with 300 ml of a 5% aqueous citric acid solution, and then washed with 300 ml of a 5% aqueous ammonia solution. The organic layer was further washed with 300 ml of a 5% aqueous citric acid solution, and then washed with 300 ml of water. The organic layer was concentrated under reduced pressure, and then reprecipitated with hexane and dried under reduced pressure to obtain 30 g of the compound A-7 (Mw=7,000). Here, a weight average molecular weight refers to a value in terms of polystyrene measured by a gel permeation chromatography (GPC) method. The measurement of the weight average molecular weight of the compound A-7 by the GPC method was performed by dissolving the polymer in tetrahydrofuran, using a high-speed GPC (HLC-8220GPC, manufactured by Tosoh Corporation), using TSKgel SuperHZ4000 (manufactured by Tosoh Corporation, 4.6 mmI.D.×15 cm) as a column, and using THF (tetrahydrofuran) as an eluent.

Here, the fluorine content rate of the compound A-7 was 53.1 mass %.

The compound A-7 corresponds to the compound having the group represented by the General Formula (24) and the group represented by the General Formula (25).

### Examples and Comparative Examples

### Preparation of Sealing Resin Composition

Each of the aforementioned compounds A-1 to A-7, as a migration inhibitor, was added to the fluorine-based resin (B-1 or B-2), which will be described later, according to the mass ratio of Table 1 below, so as to prepare a sealing resin composition. At the time of adding the migration inhibitor, the migration inhibitor was dissolved in hexafluoroisopropanol, and then added.

(Fluorine-Based Resin)

B-1: CYTOP CTL-809M (manufactured by Asahi Glass Co., Ltd.)

B-2: CYTOP CTX-809AP2 (manufactured by Asahi Glass Co., Ltd.)

TABLE 1

| | Examples | | | | | | | | | | | | | |
|---|---|---|---|---|---|---|---|---|---|---|---|---|---|---|
| | | | | | | | | | | | | Comp. | Comp. | Comp. |
| | Ex. 1 | Ex. 2 | Ex. 3 | Ex. 4 | Ex. 5 | Ex. 6 | Ex. 7 | Ex. 8 | Ex. 9 | Ex. 10 | Ex. 11 | Ex. 1 | Ex. 2 | Ex. 3 |
| Fluorine-based | B-1 | B-1 | B-1 | B-1 | B-1 | B-1 | B-2 | B-2 | B-1 | B-1 | B-1 | B-1 | B-1 | B-1 |
| resin | | | | | | | | | | | | | | |
| Migration | A-1 | A-1 | A-1 | A-1 | A-2 | A-2 | A-1 | A-2 | A-5 | A-6 | A-7 | A-1 | A-3 | A-4 |
| inhibitor | | | | | | | | | | | | | | |
| Mass ratio | 0.001 | 0.005 | 0.03 | 0.05 | 0.001 | 0.03 | 0.03 | 0.03 | 0.005 | 0.005 | 0.01 | 0.15 | 0.03 | 0.03 |
| (B)/(A) | | | | | | | | | | | | | | |

(Manufacture of Substrate with Silver Wiring)

Nanopaste NPS-JL (manufactured by Harima Chemicals Group, Inc.) was applied onto a glass epoxy substrate, which had been obtained by etching the copper portion of the glass epoxy multi-layer material MCL-E-67 (manufactured by Hitachi Chemical Co., Ltd.), by spin coating such that the film thickness after curing became 0.2 μm, and curing treatment was performed on the resultant at 180° C. for 1 hour to form a silver film. Then, PHOTEC RY-3310 (manufactured by Hitachi Chemical Co., Ltd.) was vacuum-laminated on the silver film, and exposure and development were performed on the vacuum-laminated silver film through a comb-like wiring pattern photomask of L/S=30 μm/30 μm. Then, silver of the non-covered portion of the PHOTEC RY-3310 was removed using AGRIP 940 (manufactured by Meltex Inc.), and then the PHOTEC RY-3310 was peeled off to manufacture a substrate with silver wiring for testing.

(Test Method)

(Planar Characteristics Evaluation Method)

As the evaluation method, first, the sealing resin composition was applied onto the manufactured substrate with silver wiring for testing by spin coating such that the thickness of a sealing layer (sealing film) became 1.5 μm, and curing treatment was performed on the sealing layer at 200° C. for 1 hour to prepare a wiring board for testing. The sealing layer of the wiring board for testing was observed with an optical microscope, and evaluation was performed according to the following criteria. A sealing layer of which the rank is B or higher (A) is practically usable, and a sealing layer of which the rank is A is preferable. The results of the evaluation are summarized in Table 2.

A: a sealing layer is transparent, and haze or surface unevenness is not recognized.

B: haze is slightly observed in a sealing layer, but visible light transmittance of 70% or more is secured.

C: haze or surface unevenness is remarkably observed in a sealing layer, and visible light transmittance is less than 70%.

(Adhesiveness Evaluation Method)

The adhesiveness of the sealing layer of the wiring board for testing prepared in the planar characteristics evaluation method was measured according to JIS K5600-5-6 ((ISO 2409) cross cut method, ISO adhesion tape/STANDARD of Elcometer Corporation is used), and evaluation was performed according to the following criteria. For practical use, the rank of a sealing layer needs to be B or higher (A). The results of the evaluation are summarized in Table 2.

A: a sealing layer is classified as 0 in JIS K5600-5-6

B: a sealing layer is classified as 1 to 2

C: a sealing layer is classified as 3 to 5

(Insulation Reliability Evaluation Method)

Using the wiring board for testing prepared in the planar characteristics evaluation method, lifetime measurement was performed under the conditions of a humidity of 85%, a temperature of 85° C., a pressure of 1.0 atm, and a voltage of 30 V (measuring equipment: EHS-221MD, manufactured by ESPEC Corporation).

In the evaluation method, lifetime measurement was performed under the above conditions by using the wiring board for testing, and by measuring the time T1 until the resistance value between the silver wiring becomes 1×10⁵Ω.

Next, the lifetime measurement was performed in the same manner as described above by using a wiring board for comparative testing prepared using a sealing resin composition not containing the migration inhibitor, and by measuring the time T2 until the resistance value between the silver wiring becomes 1×10⁵Ω.

The lifetime improvement effect (T1/T2) was calculated using the time T1 and the time T2 obtained. The evaluation was performed according to the following criteria. A sealing layer of which the rank is C or higher (B and A) is practically usable, and a sealing layer of which the rank is B or higher (A) is preferable. The results of the evaluation are summarized in Table 2.

A: T1/T2≧5

B: 5> T1/T2≧2

C: 2> T1/T2>1

D: 1≧T1/T2

Here, in Examples 1 to 6, Examples 9 to 11 and Comparative Examples 1 to 3 in which B-1 was used as the fluorine-based resin, the evaluation was performed using the wiring board for comparative testing in which the sealing layer was prepared by using only B-1.

In Examples 7 and 8 in which B-2 was used as the fluorine-based resin, the evaluation was performed using the wiring board for comparative testing in which the sealing layer was prepared by using only B-2.

TABLE 2

| | | | | | | | | | | | | Comp. | Comp. | Comp. |
|---|---|---|---|---|---|---|---|---|---|---|---|---|---|---|
| | Ex. 1 | Ex. 2 | Ex. 3 | Ex. 4 | Ex. 5 | Ex. 6 | Ex. 7 | Ex. 8 | Ex. 9 | Ex. 10 | Ex. 11 | Ex. 1 | Ex. 2 | Ex. 3 |
| Planar | A | A | A | A | A | B | A | A | A | A | A | C | C | C |
| characteristics | | | | | | | | | | | | | | |
| evaluation result | | | | | | | | | | | | | | |
| Adhesiveness | A | A | A | A | A | A | B | B | A | A | A | A | A | A |
| evaluation result | | | | | | | | | | | | | | |
| Insulation | C | B | A | A | C | A | A | A | A | A | B | B | D | D |
| properties | | | | | | | | | | | | | | |
| evaluation result | | | | | | | | | | | | | | |

As shown in Table 2 above, when the sealing resin composition of the present invention was used, the planar characteristics of the sealing layer were excellent, and the insulation properties between silver wiring were also excellent.

Particularly, from the comparison of Examples 1 to 4, it was found that when the mass ratio ((B)/(A)) of the migration inhibitor (B) to the fluorine-based resin (A) is equal to or more than 0.005, the insulation properties are excellent, and, particularly, when the mass ratio thereof is equal to or more than 0.03, the insulation properties are even more excellent.

Further, from the comparison of Examples 1 to 6 and Examples 7 and 8, it was found that when the fluorine-based resin contains the aforementioned silicon-containing group, the adhesiveness is more excellent.

From the comparison of Examples 2, 9, and 10, it was found that when the compound A-5 (compound represented by General Formula (22)) or the compound A-6 (compound represented by General Formula (23)) was used, the insulation properties are more excellent.

In contrast, in Comparative Example 1 in which the amount of the migration inhibitor is excessive, it was found that planar characteristics are poor. Further, in Comparative Examples 2 and 3 in which the migration inhibitor that does not satisfy the predetermined fluorine content rate is used, it was found that the insulation properties and the planar characteristics are poor.

What is claimed is:

1. A sealing resin composition, which coats silver wiring or a laminate including the silver wiring, comprising:
a fluorine-based resin (A); and
a migration inhibitor (B) having a fluorine content rate of equal to or more than 35 mass % and less than 65 mass %,
wherein the mass ratio ((B)/(A)) of the migration inhibitor (B) to the fluorine-based resin (A) is equal to or more than 0.0010 and less than 0.10.

2. The sealing resin composition according to claim 1, wherein the migration inhibitor (B) is at least one selected from the group consisting of compounds represented by General Formulae (1) to (5), a compound represented by General Formula (22), a compound represented by General Formula (23), and a compound having a group represented by General Formula (24) and a group represented by General Formula (25):
P—(CR₁═Y)ₙ-Q General Formula (1)
(in the General Formula (1), each of P and Q independently represents OH, NR₂R₃, or CHR₄R₅; each of R₂ and R₃ independently represents a hydrogen atom or a group which can be substituted with a nitrogen atom; each of R₄ and R₅ independently represents a hydrogen atom or a substituent; Y represents CR₆ or a nitrogen atom; each of R₁ and R₆ independently represents a hydrogen atom or a substituent; at least two groups of groups represented by R₁, R₂, R₃, R₄, R₅, and R₆ may be bonded to each other to form a ring; n represents an integer of 0 to 5; when n is 0, neither both P and Q are CHR₄R₅, nor both P and Q are OH; when n is 2 or more, a plurality of atomic groups represented by (CR₁═Y) may be the same as or different from each other; and at least one group of R₁ to R₆ contains a fluorine atom),
R₇—C(═O)—H General Formula (2)
(in the General Formula (2), R₇ represents an alkyl group, an alkenyl group, an alkynyl group, an aryl group, a heterocyclic group, or a group composed of any combination of these; some or all hydrogen atoms of the group represented by R₇ are substituted with fluorine atoms; and the group represented by R₇ may contain a hydroxyl group or a group represented by —COO—), 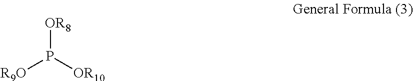
(in the General Formula (3), each of R₈, R₉, and R₁₀ independently represents an alkyl group, an alkenyl group, an alkynyl group, an aryl group, a heterocyclic group, or a group composed of any combination of these; and some or all hydrogen atoms of at least one group of R₈ to R₁₀ are substituted with fluorine atoms), 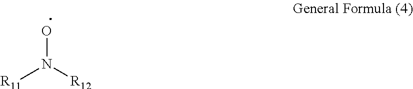
(in the General Formula (4), each of R₁₁ and R₁₂ independently represents an alkyl group, an alkenyl group, an alkynyl group, an aryl group, a heterocyclic group, or a group composed of any combination of these; and some or all hydrogen atoms of at least one group of R₁₁ and R₁₂ are substituted with fluorine atoms),
Z—SH General Formula (5)
(in the General Formula (5), Z represents an alkyl group, an alkenyl group, an alkynyl group, an aryl group, a heterocyclic group, or a group composed of any combination of these; some or all hydrogen atoms of the group represented by Z are substituted with fluorine atoms; and the group represented by Z may contain a substituent), 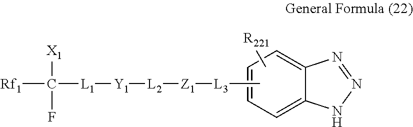
(in the General Formula (22), Rf₁ represents a fluoroalkyl group having 22 or less carbon atoms, which may have an ethereal oxygen atom and in which at least one of hydrogen atoms is substituted with a fluorine atom, or represents a fluorine atom; X₁ represents a hydrogen atom, a fluorine atom, or a trifluoromethyl group; L₁ represents a single bond or an alkylene group having 1 to 6 carbon atoms; L₂ represents a single bond or an alkylene group having 1 to 6 carbon atoms which may be substituted with a hydroxyl group or a fluorine atom; L₃ represents a single bond or an alkylene group having 1 to 6 carbon atoms; Y₁ and Z₁ represent a single bond, —CO₂—, —CO—, —OC(═O)O—, —SO₃—, —CONR₂₂₂—, —NHCOO—, —O—, —S—, —SO₂NR₂₂₂—, or —NR₂₂₂—; R₂₂₂ represents a hydrogen atom or an alkylene group having 1 to 5 carbon atoms; R₂₂₁ represents a hydrogen atom, a linear or branched alkyl group having 1 to 8 carbon atoms, or Rf₁—CFX₁-L₁-Y₁-L₂-Z₁-L₃-; and when both Y₁ and Z₁ are other than a single bond, L₂ represents an alkylene group having 1 to 6 carbon atoms which may be substituted with a fluorine atom), 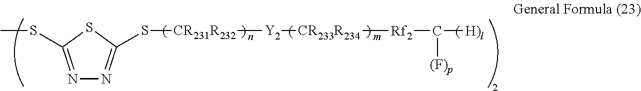
(in the General Formula (23), each of R₂₃₁ and R₂₃₂ independently represents a hydrogen atom or an alkyl group; each of R₂₃₃ and R₂₃₄ independently represents a hydrogen atom or a substituent; Y₂ represents a single bond, —CO—, or —COO—; Rf₂ represents a linear or branched perfluoroalkylene group having 1 to 20 carbon atoms, or a linear or branched perfluoroether group having 1 to 20 carbon atoms; when Y₂ is a single bond or —CO—, n represents 0, and m represents an integer of 0 to 6; when Y₂ is —COO—, n represents 1 or 2, and m represents an integer of 1 to 6; p represents an integer of 2 to 3; l represents an integer of 0 to 1; and p+l=3), and 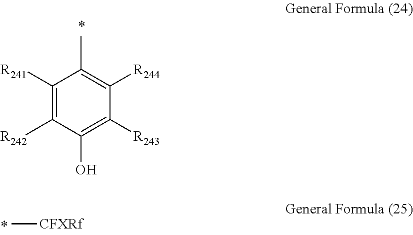
(in the General Formula (24), each of R₂₄₁, R₂₄₂, R₂₄₃, and R₂₄₄ independently represents a hydrogen atom or a substituent; and * represents a bonding position; and
in the General Formula (25), X represents a hydrogen atom, a fluorine atom, or a trifluoromethyl group; Rf represents a fluoroalkyl group having 20 or less carbon atoms, which may have an ethereal oxygen atom and in which at least one of hydrogen atoms is substituted with a fluorine atom, or represents a fluorine atom; and * represents a bonding position).

3. The sealing resin composition according to claim 2, wherein the compound represented by the General Formula (1) is at least one selected from the group consisting of compounds represented by General Formulae (6) to (21): 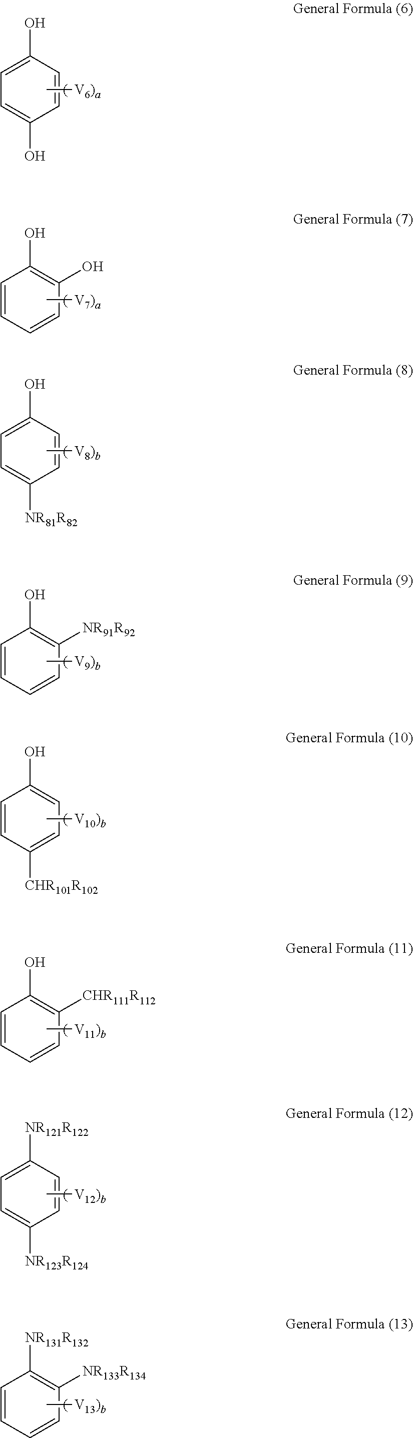 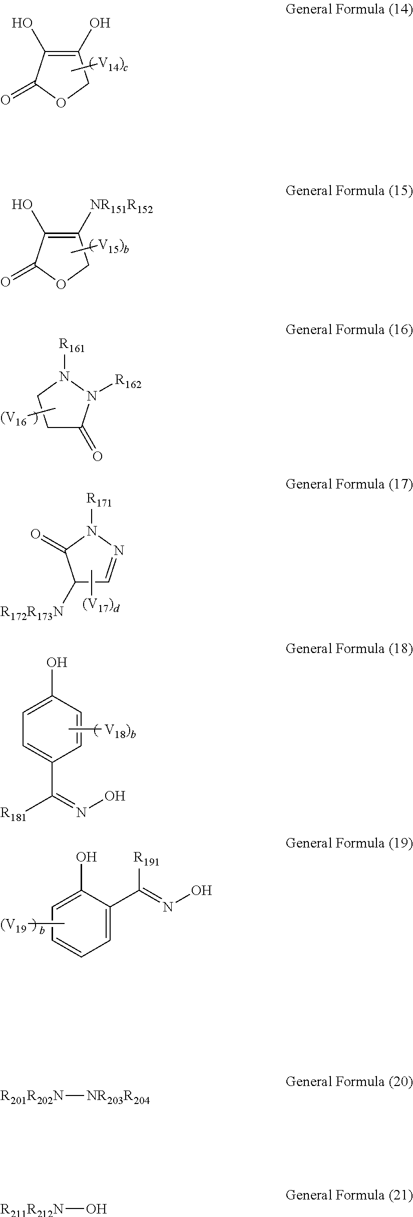
(in the General Formula (6), V₆ represents a substituent, a represents an integer of 1 to 4, and at least one of V₆ contains a fluorine atom;
in the General Formula (7), V₇ represents a substituent, a represents an integer of 1 to 4, and at least one of V₇ contains a fluorine atom;
in the General Formula (8), V₉ represents a substituent, each of R₈₁ and R₈₂ independently represents a hydrogen atom or a group which can be substituted with a nitrogen atom, b represents an integer of 0 to 4, and at least one of V₈, R₈₁, and R₈₂ contains a fluorine atom;
in the General Formula (9), V₉ represents a substituent, each of R₉₁ and R₉₂ independently represents a hydrogen atom or a group which can be substituted with a nitrogen atom, b represents an integer of 0 to 4, and at least one of V₉, R₉₁, and R₉₂ contains a fluorine atom;
in the General Formula (10), V₁₀ represents a substituent, each of R₁₀₁ and R₁₀₂ independently represents a hydrogen atom or a substituent, b represents an integer of 0 to 4, and at least one of V₁₀, R₁₀₁, and R₁₀₂ contains a fluorine atom;
in the General Formula (11), V₁₁ represents a substituent, each of R₁₁₁ and R₁₁₂ independently represents a hydrogen atom or a substituent, b represents an integer of 0 to 4, and at least one of V₁₁, R₁₁₁, and R₁₁₂ contains a fluorine atom;
in the General Formula (12), V₁₂ represents a substituent, each of R₁₂₁, R₁₂₂, R₁₂₃, and R₁₂₄ independently represents a hydrogen atom or a group which can be substituted with a nitrogen atom, b represents an integer of 0 to 4, and at least one of V₁₂, R₁₂₁, R₁₂₂, R₁₂₃, and R₁₂₄ contains a fluorine atom;
in the General Formula (13), V₁₃ represents a substituent, each of R₁₃₁, R₁₃₂, R₁₃₃, and R₁₃₄ independently represents a hydrogen atom or a group which can be substituted with a nitrogen atom, b represents an integer of 0 to 4, and at least one of V₁₃, R₁₃₁, R₁₃₂, R₁₃₃, and R₁₃₄ contains a fluorine atom;
in the General Formula (14), V₁₄ represents a substituent, c represents an integer of 1 to 2, and at least one of V₁₄ contains a fluorine atom;
in the General Formula (15), V₁₅ represents a substituent, each of R₁₅₁ and R₁₅₂ independently represents a hydrogen atom or a group which can be substituted with a nitrogen atom, b represents an integer of 0 to 4, and at least one of V₁₅, R₁₅₁, and R₁₅₂ contains a fluorine atom;
in the General Formula (16), V₁₆ represents a substituent, each of R₁₆₁ and R₁₆₂ independently represents a hydrogen atom or a group which can be substituted with a nitrogen atom, b represents an integer of 0 to 4, and at least one of V₁₆, R₁₆₁, and R₁₆₂ contains a fluorine atom;
in the General Formula (17), V₁₇ represents a substituent, each of R₁₇₁, R₁₇₂, and R₁₇₃ independently represents a hydrogen atom or a group which can be substituted with a nitrogen atom, d represents an integer of 0 or 1, and at least one of V₁₇, R₁₇₁, R₁₇₂, and R₁₇₃ contains a fluorine atom;
in the General Formula (18), V₁₈ represents a substituent, R₁₈₁ represents a hydrogen atom or a substituent, b represents an integer of 0 to 4, and at least one of V₁₈ and R₁₈₁ contains a fluorine atom;
in the General Formula (19), V₁₉ represents a substituent, R₁₉₁ represents a hydrogen atom or a substituent, b represents an integer of 0 to 4, and at least one of V₁₉ and R₁₉₁ contains a fluorine atom;
in the General Formula (20), each of R₂₀₁, R₂₀₂, R₂₀₃, and R₂₀₄ independently represents a hydrogen atom or a group which can be substituted with a nitrogen atom, and at least one of R₂₀₁, R₂₀₂, R₂₀₃, and R₂₀₄ contains a fluorine atom; and
in the General Formula (21), each of R₂₁₁ and R₂₁₂ independently represents a hydrogen atom or a group which can be substituted with a nitrogen atom, and at least one of R₂₁₁ and R₂₁₂ contains a fluorine atom).

4. The sealing resin composition according to claim 2,
wherein the compound represented by General Formula (5) is at least one selected from the group consisting of compounds represented by General Formulae (51) to (54): 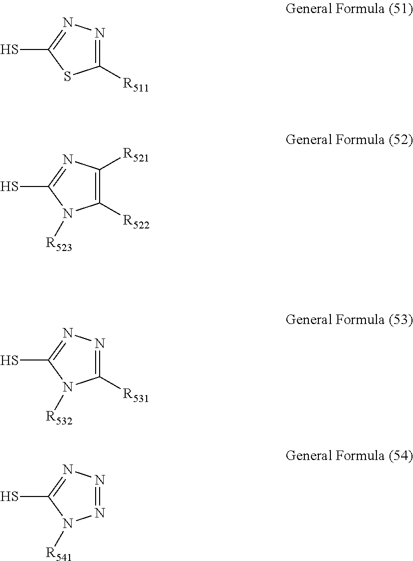
(in General Formula (51), R₅₁₁ represents a substituent containing a fluorine atom;
in General Formula (52), each of R₅₂₁ and R₅₂₂ independently represents a hydrogen atom or a substituent, R₅₂₁ and R₅₂₂ may be bonded to each other to form a ring, R₅₂₃ represents a hydrogen atom or a group which can be substituted with a nitrogen atom, and at least one group of R₅₂₁, R₅₂₂, and R₅₂₃ contains a fluorine atom;
in General Formula (53), R₅₃₁ represents a hydrogen atom or a substituent, R₅₃₂ represents a hydrogen atom or a group which can be substituted with a nitrogen atom, and at least one group of R₅₃₁ and R₅₃₂ contains a fluorine atom; and
in General Formula (54), R₅₄₁ represents a group which contains a fluorine atom and can be substituted with a nitrogen atom).

5. The sealing resin composition according to claim 4,
wherein the migration inhibitor (B) is at least one selected from the group consisting of the compounds represented by General Formula (6), General Formula (7), General Formula (10), General Formula (11), General Formula (21), General Formula (51), General Formula (53), and General Formula (54).

6. The sealing resin composition according to claim 2,
wherein the migration inhibitor (B) is at least one selected from the group consisting of a compound represented by General Formula (X), a compound represented by General Formula (Y), a polymer having a repeating unit represented by General Formula (26) and a repeating unit represented by General Formula (27), the compound represented by General Formula (22), and the compound represented by General Formula (23): 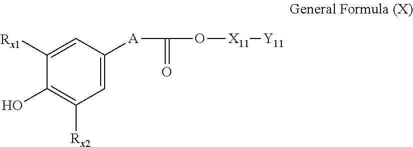
(in General Formula (X), each of Rₓ₁ and Rₓ₂ independently represents an alkyl group having 1 to 12 carbon atoms, A represents an alkylene group having 1 to 2 carbon atoms, X₁₁ represents an alkylene group having 1 to 3 carbon atoms which may contain a hydroxyl group, and Y₁₁ represents a linear perfluoroalkyl group having 4 to 12 carbon atoms), 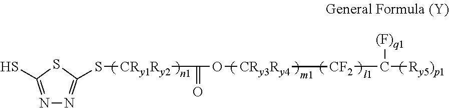
(in General Formula (Y), each of R_{y1} and R_{y2} independently represents a hydrogen atom or an alkyl group; n1 represents 1 or 2; when n is 2, a plurality of unit structures represented by CR_{y1}R_{y2} may be the same as or different from each other; each of R_{y3} and R_{y4} independently represents a hydrogen atom or a substituent; m1 represents an integer of 1 to 6; when m1 is 2 or more, a plurality of unit structures represented by CR_{y3}R_{y4} may be the same as or different from each other; R_{y3} and R_{y4} may be bonded to each other to form a ring; l1 represents an integer of 1 to 6; q1 represents 0 or 1; p1 represents 2 or 3; p1+q1 represents 3; and R_{y5} represents a perfluoroalkyl group having 1 to 14 carbon atoms), and 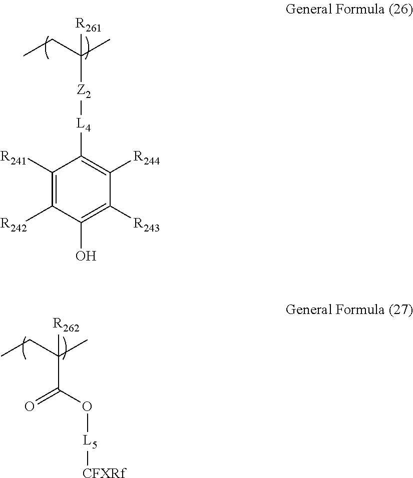
in General Formula (26) and General Formula (27), each of R₂₆₁ and R₂₆₂ independently represents a hydrogen atom or a substituted or unsubstituted alkyl group having 1 to 4 carbon atoms; Z₂ represents a single bond, an ester group, an amide group, or an ether group; L₄ represents a single bond or a divalent organic group; L₅ represents a single bond or a divalent organic group having 1 to 6 carbon atoms and containing no fluorine, and among these, an alkylene group having 2 to 4 carbon atoms is preferable; each of R₂₄₁, R₂₄₂, R₂₄₃, and R₂₄₄ independently represents a hydrogen atom or a substituent; X represents a hydrogen atom, a fluorine atom, or a trifluoromethyl group; and R_{f} represents a fluoroalkyl group having 20 or less carbon atoms which may have an ethereal oxygen atom and in which at least one of hydrogen atoms is substituted with a fluorine atom, or represents a fluorine atom).

7. The sealing resin composition according to claim 1,
wherein the fluorine-based resin (A) has at least a repeating unit represented by General Formula (P-1).

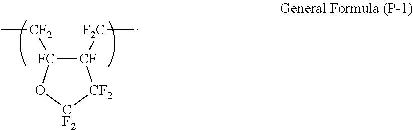

8. The sealing resin composition according to claim 1,
wherein the fluorine-based resin (A) has a silicon-containing group that has a hydroxyl group or a hydrolyzable group bonded to a silicon atom and that can be crosslinked by forming a siloxane bond.

9. A sealing film, which coats silver wiring or a laminate including the silver wiring, comprising:
a fluorine-based resin (A); and
a migration inhibitor (B) having a fluorine content rate of equal to or more than 35 mass % and less than 65 mass %,
wherein the mass ratio ((B)/(A)) of the migration inhibitor (B) to the fluorine-based resin (A) is equal to or more than 0.0010 and less than 0.10.

10. The sealing film according to claim 9, wherein the migration inhibitor (B) is at least one selected from the group consisting of compounds represented by General Formulae (1) to (5), a compound represented by General Formula (22), a compound represented by General Formula (23), and a compound having a group represented by General Formula (24) and a group represented by General Formula (25):
P—(CR₁═Y)ₙ-Q General Formula (1)
(in the General Formula (1), each of P and Q independently represents OH, NR₂R₃, or CHR₄R₅; each of R₂ and R₃ independently represents a hydrogen atom or a group which can be substituted with a nitrogen atom; each of R₄ and R₅ independently represents a hydrogen atom or a substituent; Y represents CR₆ or a nitrogen atom; each of R₁ and R₆ independently represents a hydrogen atom or a substituent; at least two groups of groups represented by R₁, R₂, R₃, R₄, R₅, and R₆ may be bonded to each other to form a ring; n represents an integer of 0 to 5; when n is 0, neither both P and Q are CHR₄R₅, nor both P and Q are OH; when n is 2 or more, a plurality of atomic groups represented by (CR₁═Y) may be the same as or different from each other; and at least one of R₁ to R₆ contains a fluorine atom),
R₇—C(═O)—H General Formula (2)
(in the General Formula (2), R₇ represents an alkyl group, an alkenyl group, an alkynyl group, an aryl group, a heterocyclic group, or a group composed of any combination of these; some or all hydrogen atoms of the group represented by R₇ are substituted with fluorine atoms; and the group represented by R₇ may contain a hydroxyl group or a group represented by —COO—), 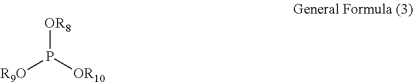
(in the General Formula (3), each of R₈, R₉, and R₁₀ independently represents an alkyl group, an alkenyl group, an alkynyl group, an aryl group, a heterocyclic group, or a group composed of any combination of these; and some or all hydrogen atoms of at least one group of R₈ to R₁₀ are substituted with fluorine atoms), 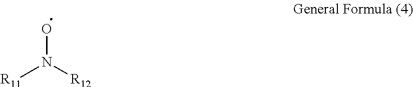
(in the General Formula (4), each of R₁₁ and R₁₂ independently represents an alkyl group, an alkenyl group, an alkynyl group, an aryl group, a heterocyclic group, or a group composed of any combination of these; and some or all hydrogen atoms of at least one group of R₁₁ and R₁₂ are substituted with fluorine atoms),
Z—SH General Formula (5)
(in the General Formula (5), Z represents an alkyl group, an alkenyl group, an alkynyl group, an aryl group, a heterocyclic group, or a group composed of any combination of these; some or all hydrogen atoms of the group represented by Z are substituted with fluorine atoms; and the group represented by Z may contain a substituent), 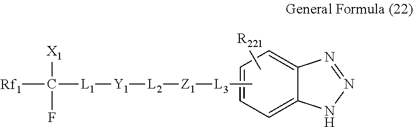
(in the General Formula (22), Rf₁ represents a fluoroalkyl group having 22 or less carbon atoms, which may have an ethereal oxygen atom and in which at least one of hydrogen atoms is substituted with a fluorine atom, or represents a fluorine atom; X₁ represents a hydrogen atom, a fluorine atom, or a trifluoromethyl group; L₁ represents a single bond or an alkylene group having 1 to 6 carbon atoms; L₂ represents a single bond or an alkylene group having 1 to 6 carbon atoms which may be substituted with a hydroxyl group or a fluorine atom; L₃ represents a single bond or an alkylene group having 1 to 6 carbon atoms; Y₁ and Z₁ represent a single bond, —CO₂—, —CO—, —OC(═O)O—, —SO₃—, —CONR₂₂₂—, —NHCOO—, —O—, —S—, —SO₂NR₂₂₂—, or —NR₂₂₂—; R₂₂₂ represents a hydrogen atom or an alkylene group having 1 to 5 carbon atoms; R₂₂₁ represents a hydrogen atom, a linear or branched alkyl group having 1 to 8 carbon atoms, or Rf₁—CFX₁-L₁-Y₁-L₂-Z₁-L₃-; and when both Y₁ and Z₁ are other than a single bond, L₂ represents an alkylene group having 1 to 6 carbon atoms which may be substituted with a fluorine atom), 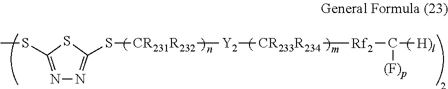
(in the General Formula (23), each of R₂₃₁ and R₂₃₂ independently represents a hydrogen atom or an alkyl group; each of R₂₃₃ and R₂₃₄ independently represents a hydrogen atom or a substituent; Y₂ represents a single bond, —CO—, or —COO—; Rf₂ represents a linear or branched perfluoroalkylene group having 1 to 20 carbon atoms, or a linear or branched perfluoroether group having 1 to 20 carbon atoms; when Y₂ is a single bond or —CO—, n represents 0, and m represents an integer of 0 to 6; when Y₂ is —COO—, n represents 1 or 2, and m represents an integer of 1 to 6; p represents an integer of 2 to 3; l represents an integer of 0 to 1; and p+l=3), and 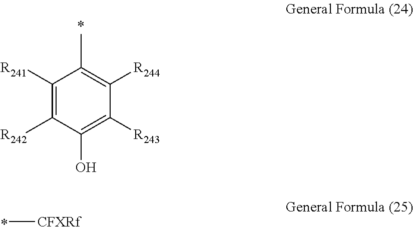
(in the General Formula (24), each of R₂₄₁, R₂₄₂, R₂₄₃, and R₂₄₄ independently represents a hydrogen atom or a substituent; and * represents a bonding position; and
in the General Formula (25), X represents a hydrogen atom, a fluorine atom, or a trifluoromethyl group; and Rf represents a fluoroalkyl group having 20 or less carbon atoms, which may have an ethereal oxygen atom and in which at least one of hydrogen atoms is substituted with a fluorine atom, or represents a fluorine atom).

11. The sealing film according to claim 10, wherein the compound represented by the General Formula (1) is at least one selected from the group consisting of compounds represented by General Formulae (6) to (21): 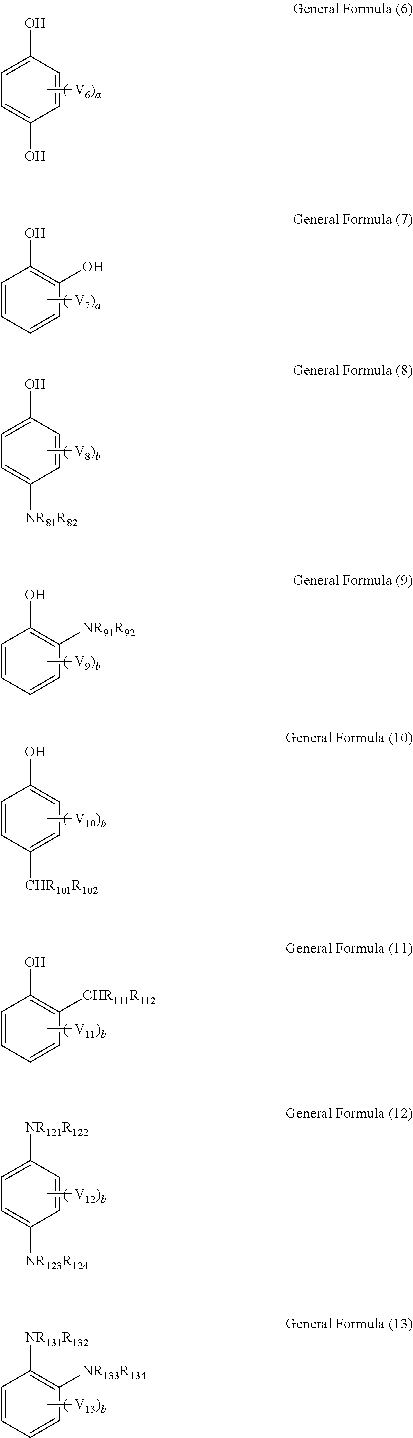 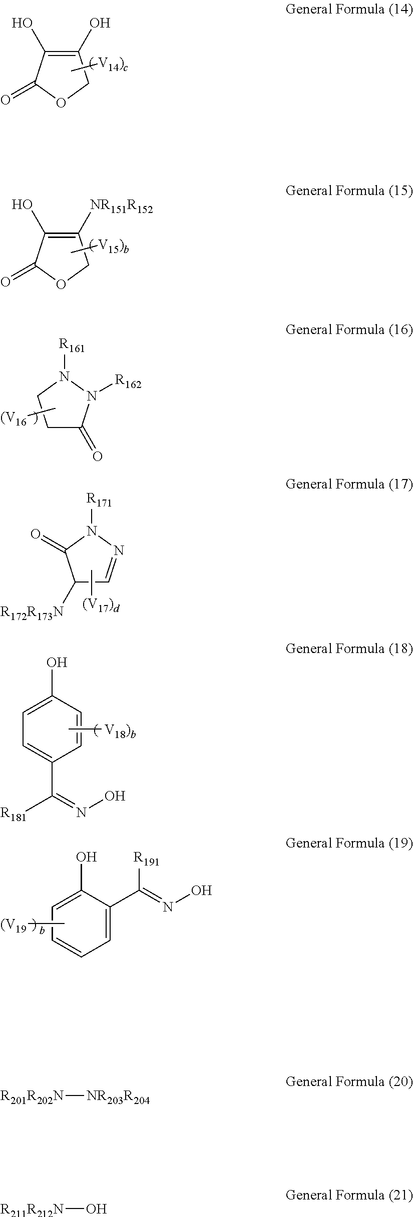
(in the General Formula (6), V₆ represents a substituent, a represents an integer of 1 to 4, and at least one of V₆ contains a fluorine atom;
in the General Formula (7), V₇ represents a substituent, a represents an integer of 1 to 4, and at least one of V₇ contains a fluorine atom;
in the General Formula (8), V₈ represents a substituent, each of R₈₁ and R₈₂ independently represents a hydrogen atom or a group which can be substituted with a nitrogen atom, b represents an integer of 0 to 4, and at least one of V₈, R₈₁, and R₈₂ contains a fluorine atom;
in the General Formula (9), V₉ represents a substituent, each of R₉₁ and R₉₂ independently represents a hydrogen atom or a group which can be substituted with a nitrogen atom, b represents an integer of 0 to 4, and at least one of V₉, R₉₁, and R₉₂ contains a fluorine atom;
in the General Formula (10), V₁₀ represents a substituent, each of R₁₀₁ and R₁₀₂ independently represents a hydrogen atom or a substituent, b represents an integer of 0 to 4, and at least one of V₁₀, R₁₀₁, and R₁₀₂ contains a fluorine atom;
in the General Formula (11), V₁₁ represents a substituent, each of R₁₁₁ and R₁₁₂ independently represents a hydrogen atom or a substituent, b represents an integer of 0 to 4, and at least one of V₁₁, R₁₁₁, and R₁₁2 contains a fluorine atom;
in the General Formula (12), V₁₂ represents a substituent, each of R₁₂₁, R₁₂₂, R₁₂₃, and R₁₂₄ independently represents a hydrogen atom or a group which can be substituted with a nitrogen atom, b represents an integer of 0 to 4, and at least one of V₁₂, R₁₂₁, R₁₂₂, R₁₂₃, and R₁₂₄ contains a fluorine atom;
in the General Formula (13), V₁₃ represents a substituent, each of R₁₃₁, R₁₃₂, R₁₃₃, and R₁₃₄ independently represents a hydrogen atom or a group which can be substituted with a nitrogen atom, b represents an integer of 0 to 4, and at least one of V₁₃, R₁₃₁, R₁₃₂, R₁₃₃, and R₁₃₄ contains a fluorine atom;
in the General Formula (14), V₁₄ represents a substituent, c represents an integer of 1 to 2, and at least one of V₁₄ contains a fluorine atom;
in the General Formula (15), V₁₅ represents a substituent, each of R₁₅₁ and R₁₅₂ independently represents a hydrogen atom or a group which can be substituted with a nitrogen atom, b represents an integer of 0 to 4, and at least one of V₁₅, R₁₅₁, and R₁₅₂ contains a fluorine atom;
in the General Formula (16), V₁₆ represents a substituent, each of R₁₆₁ and R₁₆₂ independently represents a hydrogen atom or a group which can be substituted with a nitrogen atom, b represents an integer of 0 to 4, and at least one of V₁₆, R₁₆₁, and R₁₆₂ contains a fluorine atom;
in the General Formula (17), V₁₇ represents a substituent, each of R₁₇₁, R₁₇₂, and R₁₇₃ independently represents a hydrogen atom or a group which can be substituted with a nitrogen atom, d represents an integer of 0 or 1, and at least one of V₁₇, R₁₇₁, R₁₇₂, and R₁₇₃ contains a fluorine atom;
in the General Formula (18), V₁₈ represents a substituent, R₁₈₁ represents a hydrogen atom or a substituent, b represents an integer of 0 to 4, and at least one of V₁₈ and R₁₈₁ contains a fluorine atom;
in the General Formula (19), V₁₉ represents a substituent, R₁₉₁ represents a hydrogen atom or a substituent, b represents an integer of 0 to 4, and at least one of V₁₉ and R₁₉₁ contains a fluorine atom;
in the General Formula (20), each of R₂₀₁, R₂₀₂, R₂₀₃, and R₂₀₄ independently represents a hydrogen atom or a group which can be substituted with a nitrogen atom, and at least one of R₂₀₁, R₂₀₂, R₂₀₃, and R₂₀₄ contains a fluorine atom; and
in the General Formula (21), each of R₂₁₁ and R₂₁₂ independently represents a hydrogen atom or a group which can be substituted with a nitrogen atom, and at least one of R₂₁₁ and R₂₁₂ contains a fluorine atom).

12. The sealing film according to claim 10,
wherein the compound represented by General Formula (5) is at least one selected from the group consisting of compounds represented by General Formulae (51) to (54): 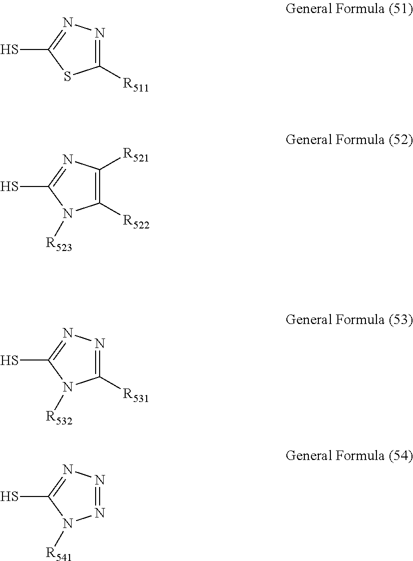
(in General Formula (51), R₅₁₁ represents a substituent containing a fluorine atom;
in General Formula (52), each of R₅₂₁ and R₅₂₂ independently represents a hydrogen atom or a substituent, R₅₂₁ and R₅₂₂ may be bonded to each other to form a ring, R₅₂₃ represents a hydrogen atom or a group which can be substituted with a nitrogen atom, and at least one group of R₅₂₁, R₅₂₂, and R₅₂₃ contains a fluorine atom;
in General Formula (53), R₅₃₁ represents a hydrogen atom or a substituent, R₅₃₂ represents a hydrogen atom or a group which can be substituted with a nitrogen atom, and at least one group of R₅₃₁ and R₅₃₂ contains a fluorine atom; and
in General Formula (54), R₅₄₁ represents a group which contains a fluorine atom and can be substituted with a nitrogen atom).

13. The sealing film according to claim 12,
wherein the migration inhibitor (B) is at least one selected from the group consisting of the compounds represented by General Formula (6), General Formula (7), General Formula (10), General Formula (11), General Formula (21), General Formula (51), General Formula (53), and General Formula (54).

14. The sealing film according to claim 10,
wherein the migration inhibitor (B) is at least one selected from the group consisting of a compound represented by General Formula (X), a compound represented by General Formula (Y), a polymer having a repeating unit represented by General Formula (26) and a repeating unit represented by General Formula (27), the compound represented by General Formula (22), and the compound represented by General Formula (23): 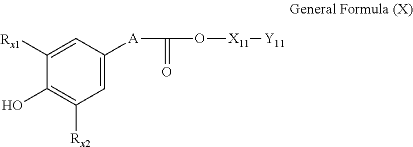
(in General Formula (X), each of Rₓ₁ and Rₓ₂ independently represents an alkyl group having 1 to 12 carbon atoms, A represents an alkylene group having 1 to 2 carbon atoms, X₁₁ represents an alkylene group having 1 to 3 carbon atoms which may contain a hydroxyl group, and Y₁₁ represents a linear perfluoroalkyl group having 4 to 12 carbon atoms), 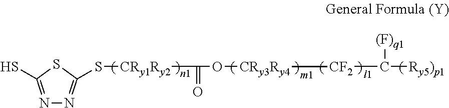
(in General Formula (Y), each of R_{y1} and R_{y2} independently represents a hydrogen atom or an alkyl group; n1 represents 1 or 2; when n is 2, a plurality of unit structures represented by CR_{y1}R_{y2} may be the same as or different from each other; each of R_{y3} and R_{y4} independently represents a hydrogen atom or a substituent; m1 represents an integer of 1 to 6; when m1 is 2 or more, a plurality of unit structures represented by CR_{y3}R_{y4} may be the same as or different from each other; R_{y3} and R_{y4} may be bonded to each other to form a ring; l1 represents an integer of 1 to 6; q1 represents 0 or 1; p1 represents 2 or 3; p1+q1 represents 3; and R_{y5} represents a perfluoroalkyl group having 1 to 14 carbon atoms), and 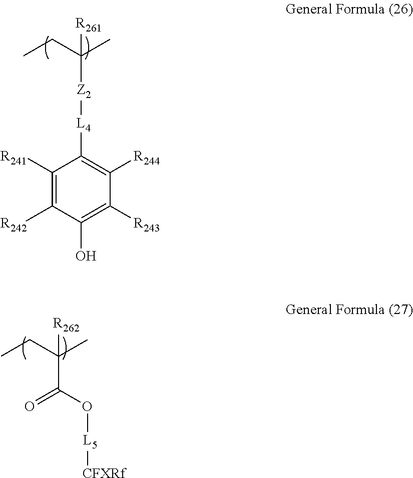
(in General Formula (26) and General Formula (27), each of R₂₆₁ and R₂₆₂ independently represents a hydrogen atom or a substituted or unsubstituted alkyl group having 1 to 4 carbon atoms; Z₂ represents a single bond, an ester group, an amide group, or an ether group; L₄ represents a single bond or a divalent organic group; L₅ represents a single bond or a divalent organic group having 1 to 6 carbon atoms and containing no fluorine, and among these, an alkylene group having 2 to 4 carbon atoms is preferable; each of R₂₄₁, R₂₄₂, R₂₄₃, and R₂₄₄ independently represents a hydrogen atom or a substituent; X represents a hydrogen atom, a fluorine atom, or a trifluoromethyl group; and R_{f} represents a fluoroalkyl group having 20 or less carbon atoms which may have an ethereal oxygen atom and in which at least one of hydrogen atoms is substituted with a fluorine atom, or represents a fluorine atom).

15. The sealing film according to claim 9,
wherein the fluorine-based resin (A) is a polymer compound having at least a repeating unit represented by General Formula (P-1) below.

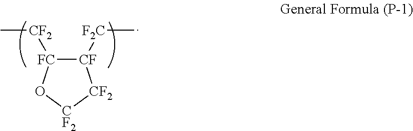

16. The sealing film according to claim 9,
wherein the fluorine-based resin (A) has a silicon-containing group that has a hydroxyl group or a hydrolyzable group bonded to a silicon atom and that can be crosslinked by forming a siloxane bond.

17. A wiring board comprising:
a substrate;
silver wiring disposed on the substrate; and
the sealing film according to claim 9 disposed on the silver wiring.

18. A TFT device comprising the sealing film according to claim 9.

19. An OLED device comprising the sealing film according to claim 9.

20. An LED device comprising the sealing film according to claim 9.
